(19) United States
(12) Patent Application Publication
(10) Pub. No.: US 2026/0068180 A1
(43) Pub. Date: Mar. 5, 2026

(54) SEMICONDUCTOR DEVICE AND METHOD FOR FABRICATING THE SAME

(71) Applicant: SK hynix Inc., Gyeonggi-do (KR)

(72) Inventors: Il Do KIM, Gyeonggi-do (KR); Jae Sun SONG, Gyeonggi-do (KR); Seung Bum KIM, Gyeonggi-do (KR)

(21) Appl. No.: 19/070,533

(22) Filed: Mar. 5, 2025

(30) Foreign Application Priority Data
Aug. 30, 2024 (KR) 10-2024-0117590

(51) Int. Cl. H10B 80/00; H01L 25/065; H10B 12/00

(52) U.S. Cl. CPC H10B 80/00; H10B 12/03; H10B 12/05; H10B 12/315

(57) ABSTRACT

A semiconductor device may include high-integrated memory cells, and a method for fabricating the semiconductor device may include forming a first mold stack and a first bonding layer on a substrate; forming a second mold stack and a second bonding layer on a sacrificial substrate; flipping the sacrificial substrate and bonding the first and second bonding layers; removing the sacrificial substrate; and forming a plurality of memory cells vertically stacked in the first and second mold stacks.

### CROSS-REFERENCE TO RELATED APPLICATIONS

The present application claims priority under 35 U.S.C 119(a) to Korean Patent Application No. 10-2024-0117590, filed on Aug. 30, 2024, which is incorporated herein by reference in its entirety.

### BACKGROUND

### 1. Field

Various embodiments of the present disclosure relate to a semiconductor device, and more particularly, to a semiconductor device including three-dimensional (3D) memory cells, and a method for fabricating the semiconductor device.

### 2. Description of the Related Art

Recently, in order to cope with the trend of large capacity and miniaturization of a memory device, a three-dimensional (3D) memory device in which a plurality of memory cells are stacked has been proposed. Intensive research is currently underway for improving the structural as well performance characteristics of 3D memory devices.

### SUMMARY

Embodiments of the present disclosure are directed to a semiconductor device including high-integrated memory cells, and a method for fabricating the semiconductor device.

In accordance with an embodiment of the present disclosure, a method for fabricating a semiconductor device may include forming a first mold stack and a first bonding layer on a substrate; forming a second mold stack and a second bonding layer on a sacrificial substrate; flipping the sacrificial substrate and bonding the first and second bonding layers; removing the sacrificial substrate; and forming a plurality of memory cells vertically stacked in the first and second mold stacks.

In accordance with an embodiment of the present disclosure, a semiconductor device may include a lower-level array stack of first memory cells; an upper-level array stack of second memory cells; a bonding structure between the lower-level array stack and the upper-level array stack; and a vertical conductive line penetrating the bonding structure and coupled in common to the first memory cells and the second memory cells.

In accordance with an embodiment of the present disclosure, a semiconductor device may include a lower-level array stack in which first memory cells are vertically stacked; an upper-level array stack in which second memory cells are vertically stacked; a bonding structure between the lower-level array stack and the upper-level array stack; a bit line penetrating the bonding structure and coupled in common to the first memory cells and the second memory cells; and a common plate penetrating the bonding structure and coupled in common to the first memory cells and the second memory cells.

In accordance with an embodiment of the present disclosure, a semiconductor device may include a stack structure of a lower-level array stack, a bonding structure and an upper-level array stack, wherein the lower-level array stack and the upper-level array stack may each include a three-dimensional array of memory cells vertically stacked, and the three-dimensional array may include horizontally-oriented switching elements, vertically-oriented first conductive lines, and horizontally-oriented data storage elements.

In accordance with an embodiment of the present disclosure, a method for fabricating a semiconductor device may include forming a first mold stack including a plurality of mold layers on a substrate; forming a first bonding layer on the first mold stack; forming a second mold stack including a plurality of mold layers on a sacrificial substrate; forming a second bonding layer on the second mold stack; performing a wafer bonding process using the first bonding layer and the second bonding layer to form a mold stack with a high stack including the first mold stack and the second mold stack; removing the sacrificial substrate; and forming memory cells with a high stack in the mold stack with the high stack.

In accordance with an embodiment of the present disclosure, a method for fabricating a semiconductor device may include forming a first mold stack including first and second mold layers epitaxially grown on a substrate; forming a first bonding layer on the first mold stack; forming a second mold stack including first and second mold layers epitaxially grown on a sacrificial substrate; forming a second bonding layer on the second mold stack; bonding the first bonding layer and the second bonding layer to form a mold stack with a high stack including the first and second mold stacks; and removing the sacrificial substrate. The method may further include forming memory cells with a high stack in the mold stack with the high stack.

In accordance with an embodiment of the present disclosure, a method for fabricating a semiconductor device may include forming a first structure comprising a first mold stack and a first bonding layer on a substrate; forming a second structure comprising a second mold stack and a second bonding layer on a sacrificial substrate; flipping the second structure and positioning the flipped second structure on the first structure with the first and second bonding layers being adjacent to each other; bonding the first and second bonding layers; after bonding the first and second bonding layers removing the sacrificial substrate; and forming a plurality of memory cells vertically stacked in the first and second mold stacks. Forming the memory cells vertically stacked may include replacing the first mold stack with the memory cells and forming a lower-level array stack of the memory cells; and replacing the second mold stack with the memory cells and forming an upper-level array stack of the memory cells.

### BRIEF DESCRIPTION OF THE DRAWINGS

FIG. 1A is a schematic perspective view illustrating a memory cell in accordance with an embodiment of the present disclosure.

FIG. 1B is a schematic cross-sectional view of the memory cell illustrated in FIG. 1A.

FIG. 2 is a schematic perspective view illustrating a semiconductor device in accordance with an embodiment of the present disclosure.

FIG. 3 is a schematic plan view illustrating a semiconductor device in accordance with an embodiment of the present disclosure.

FIG. 4A is a cross-sectional view of the semiconductor device taken along line A-A′ illustrated in FIG. 3.

FIG. 4B is a cross-sectional view of the semiconductor device taken along line B-B′ illustrated in FIG. 3.

FIGS. 5 to 27 illustrate various views of a semiconductor device formed utilizing a method for fabricating the semiconductor device in accordance with an embodiment of the present disclosure.

FIG. 28 is a schematic cross-sectional view of a semiconductor device in accordance with an embodiment of the present disclosure.

FIGS. 29A and 29B are schematic cross-sectional views of a semiconductor device in accordance with embodiments of the present disclosure.

FIGS. 30A and 30B illustrate various views illustrating a stack assembly in accordance with embodiments of the present disclosure.

### DETAILED DESCRIPTION

Various embodiments of the present disclosure may be described herein with reference to cross-sectional views, plan views and block diagrams, which are ideal schematic views of a semiconductor device. It is noted that the structures of the drawings may be modified by fabricating techniques and/or tolerances. The embodiments of the present disclosure are not limited to the described embodiments and the specific structures illustrated in the drawings, but may include other embodiments, or modifications of the described embodiments including any changes in the structures that may be produced according to requirements of the fabricating process. Accordingly, the regions illustrated in the drawings have schematic attributes, and the shapes of the regions illustrated in the drawings are intended to illustrate specific structures of regions of the elements, and are not intended to limit the scope of the embodiments of the present disclosure.

The following embodiment relates to three-dimensional (3D) memory cells with memory cells vertically stacked for increasing the memory cell density and reducing parasitic capacitance.

According to the following embodiment, a three-dimensional (3D) memory cell array with a high stack may be formed by combining epitaxial growth of semiconductor layers and a wafer bonding process.

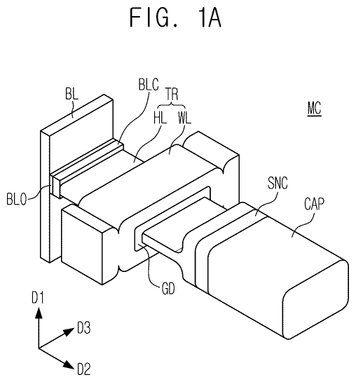

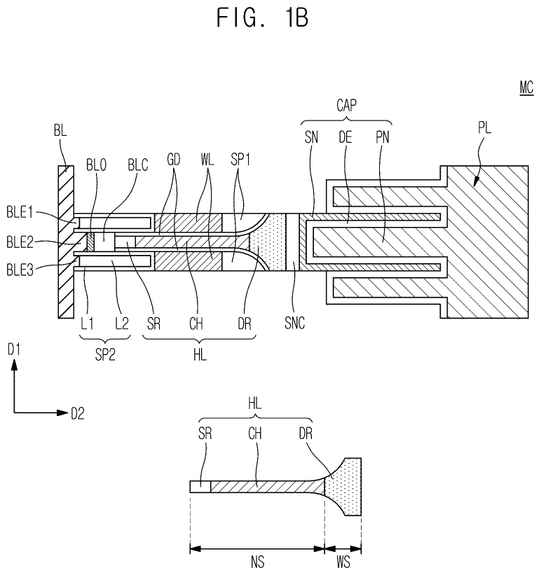

FIG. 1A is a schematic perspective view illustrating a memory cell MC in accordance with an embodiment of the present disclosure. FIG. 1B is a schematic cross-sectional view of the memory cell MC illustrated in FIG. 1A.

Referring to FIGS. 1A and 1B, the memory cell MC may include a first conductive line BL, a switching element TR, and a data storage element CAP.

The first conductive line BL may be vertically oriented in a first direction D1. The first conductive line BL may include a bit line. The first conductive line BL may be referred to as a “vertical conductive line”, a “vertically-oriented bit line”, a “vertically-extending bit line”, or a “pillar-shaped bit line”. The first conductive line BL may include a conductive material. The first conductive line BL may include a silicon-based material, a metal-based material, or a combination thereof. The first conductive line BL may include polysilicon, metal, metal nitride, metal silicide, or a combination thereof. The first conductive line BL may include polysilicon, titanium nitride, tungsten, or a combination thereof. For example, the first conductive line BL may include a titanium nitride/tungsten (TiN/W) stack in which titanium nitride and tungsten are sequentially stacked.

The switching element TR has a function of controlling voltage or current supply to the data storage element CAP during a data write operation and a data read operation performed onto the data storage element CAP. The switching element TR may include a nano sheet HL, a nano sheet dielectric layer GD, and a second conductive line WL. The second conductive line WL may include a horizontal conductive line or a horizontal word line, and the nano sheet HL may include an active layer. The switching element TR may include a transistor, and in this case, the second conductive line WL may serve as a gate electrode. The switching element TR may also be referred to as a “nano sheet transistor”, an “access element” or a “selection element”. The second conductive line WL may be referred to as a “horizontal gate electrode” or a “horizontal word line”.

The nano sheet HL may extend in a second direction D2 that intersects with the first direction D1. The second conductive line WL may extend in a third direction D3 that intersects with the first direction D1 and the second direction D2. The first direction D1 may be a vertical direction, the second direction D2 may be a first horizontal direction, and the third direction D3 may be a second horizontal direction. The nano sheet HL may extend in the first horizontal direction, i.e., the second direction D2, and the second conductive line WL may extend in the second horizontal direction, i.e., the third direction D3. The nano sheet HL may be referred to as a “horizontal layer”.

The nano sheet HL may include a channel CH, a first doped region SR between the channel CH and the first conductive line BL, and a second doped region DR between the channel CH and the data storage element CAP. The first doped region SR may be electrically coupled to the first conductive line BL via a first conductive node BLC and an ohmic contact layer BLO. The second doped region DR may be electrically coupled to the data storage element CAP. The height of the second doped region DR in the first direction D1 may be greater than the heights of the first doped region SR and the channel CH in the first direction D1. The length of the second doped region DR in the second direction D2 may be less than that of the channel CH in the second direction D2. The lengths of the first doped region SR, the channel CH and the second doped region DR in the third direction D3 may be equal to one another.

The nano sheet HL may include a first region NS and a second region WS that are horizontally adjacent to each other in the second direction D2. More specifically, the second region WS may extend from an end of the first region NS toward the second contact node SNC. The second region WS may have a thickness that gradually increases in the second direction D2 from the first region NS toward the data storage element CAP between the first region NS and the data storage element CAP. An average vertical height or thickness of the second region WS in the first direction DI may be greater than that of the first region NS. Hereinafter, the first region NS is referred to as a “narrow sheet”, and the second region WS is referred to as a “wide sheet”.

The narrow sheet NS may have a flat plate shape. The wide sheet WS may have a fan-like shape. The wide sheet WS may have a thickness that gradually increases in the second direction D2. The narrow sheet NS may be referred to as a “flat plate-shaped sheet”, and the wide sheet WS may be referred to as a “fan-like shaped sheet”. A boundary portion between the narrow sheet NS and the wide sheet WS may have a curvature.

The first doped region SR and the channel CH may be disposed in the narrow sheet NS. The second doped region DR may be disposed in the wide sheet WS. The channel CH formed in the narrow sheet NS may be referred to as a “narrow channel” or a “flat channel”. One side of the wide sheet WS facing toward the data storage element CAP and one side of the second doped region DR contacting the narrow sheet NS may each have a flat shape.

In some embodiments, a portion of the second doped region DR may extend to be disposed in the narrow sheet NS (not shown). In such embodiments, the second doped region DR may include a thick portion disposed in the wide sheet WS and a thin portion disposed in the narrow sheet NS.

A horizontal length of the wide sheet WS in the second direction D2 may be less than that of the narrow sheet NS. For example, a horizontal length of the wide sheet WS in the second direction D2 may be less than ½, or ⅓ than the horizontal length of the narrow sheet NS. The narrow sheet NS may be referred to as a “long sheet”, and the wide sheet WS may be referred to as a “short sheet”.

The nano sheet HL may include a semiconductive material. For example, the nano sheet HL may include polysilicon, monocrystalline silicon, germanium, or silicon-germanium. In some embodiments, the nano sheet HL may include an oxide semiconductor material. For example, the oxide semiconductor material may include indium gallium zinc oxide (IGZO), indium tin zinc oxide (InSnZnO), or zinc tin oxide (ZnSnO), or a combination thereof. In some embodiments, the nano sheet HL may include a conductive metal oxide. In some embodiments, the nano sheet HL may include a two-dimensional material, for example, molybdenum disulfide (MoS₂), tungsten disulfide (WS₂), or molybdenum diselenide (MoSe₂).

When the nano sheet HL is formed of the oxide semiconductor material, the channel CH may also be formed of oxide semiconductor material, and the first and second doped regions SR and DR may be omitted. The nano sheet HL may also be referred to as an “active layer” or a “thin body”.

The first doped region SR and the second doped region DR may be doped with impurities of the same conductivity type. For example, the first doped region SR and the second doped region DR may be doped with an N-type conductive impurity or a P-type conductive impurity. The first doped region SR and the second doped region DR may include at least one impurity selected from among arsenic (As), phosphorus (P), boron (B), indium (In), and combinations thereof. The first doped region SR may be electrically coupled to the first conductive line BL. The second doped region DR may be electrically coupled to the data storage element CAP. The first and second doped regions SR and DR may be referred to as “first and second source/drain regions”.

The nano sheet HL may be horizontally oriented in the second direction D2 with a first end thereof electrically coupled to the first conductive line BL, and a second end thereof electrically coupled to the data storage element CAP.

The second conductive line WL may have a gate all around (GAA) structure surrounding the nano sheet HL and extending in the third direction D3. The nano sheet dielectric layer GD may be formed between the nano sheet HL and the second conductive line WL. The nano sheet dielectric layer GD may surround a portion of the nano sheet HL, for example, the channel CH of the nano sheet HL. The second conductive line WL may surround the nano sheet HL on the nano sheet dielectric layer GD. The switching element TR may include a GAA transistor.

The second conductive line WL may include a metal-based material, a semiconductive material, or a combination thereof. The second conductive line WL may include molybdenum, molybdenum nitride, ruthenium, titanium nitride, tungsten, polysilicon, or a combination thereof. For example, the second conductive line WL may include a TiN/W stack in which titanium nitride and tungsten are sequentially stacked. The second conductive line WL may include an N-type work function material or a P-type work function material. The N-type work function material may have a low work function of approximately 4.5 eV or lower, and the P-type work function material may have a high work function of approximately 4.5 eV or higher. The second conductive line WL may include a stack of the low work function material and the high work function material.

The nano sheet dielectric layer GD may be disposed between the nano sheet HL and the second conductive line WL. The nano sheet dielectric layer GD may be referred to as a “gate dielectric layer” or a “channel-side dielectric layer”. The nano sheet dielectric layer GD may include silicon oxide, silicon nitride, metal oxide, metal oxide nitride, metal silicate, a high-k material, a ferroelectric material, an anti-ferroelectric material, or a combination thereof. The nano sheet dielectric layer GD may include SiO₂, Si₃N₄, HfO₂, Al₂O₃, ZrO₂, AlON, HfON, HfSiO, HfSiON, HfZrO, or a combination thereof. The nano sheet dielectric layer GD may be formed by deposition of a nano sheet dielectric material and thermal oxidation of the nano sheet HL. In some embodiments, the nano sheet dielectric layer GD may be deposited on the nano sheet HL or be formed by the thermal oxidation of the nano sheet HL.

The data storage element CAP may include a memory element such as a capacitor. The data storage element CAP may be horizontally disposed in the second direction D2 from the switching element TR. The data storage element CAP may include a first electrode SN, a second electrode PN on the first electrode SN, and a dielectric layer DE between the first electrode SN and the second electrode PN. The first electrode SN may horizontally extend from the nano sheet HL in the second direction D2. The first electrode SN, the dielectric layer DE and the second electrode PN may be horizontally disposed in the second direction D2. The first electrode SN may include an inner space and a plurality of outer surfaces, and the inner space of the first electrode SN may include a plurality of inner surfaces. The outer surfaces of the first electrode SN may include a vertical outer surface and a plurality of horizontal outer surfaces. The vertical outer surface of the first electrode SN may vertically extend in the first direction D1, and the horizontal outer surfaces of the first electrode SN may horizontally extend in the second direction D2 or the third direction D3. The inner space of the first electrode SN may be a three-dimensional space. The dielectric layer DE may conformally cover the inner and outer surfaces of the first electrode SN. The second electrode PN may be disposed in the inner space of the first electrode SN on the dielectric layer DE. Some of the outer surfaces of the first electrode SN may be electrically coupled to the second doped region DR of the nano sheet HL. The second electrode PN of the data storage element CAP may be coupled to a common plate PL. The first electrode SN may be referred to as a “storage node”.

The data storage element CAP may have a three-dimensional structure. The first electrode SN may have a three-dimensional structure, and the first electrode SN having the three-dimensional structure may have a three-dimensional structure that is horizontally oriented in the second direction D2. As an example of the three-dimensional structure, the first electrode SN may have a cylindrical shape. The cylindrical shape of the first electrode SN may include cylindrical inner surfaces and cylindrical outer surfaces. Some of the cylindrical outer surfaces of the first electrode SN may be electrically coupled to the second doped region DR of the nano sheet HL. The dielectric layer DE and the second electrode PN may be disposed on the cylindrical inner surfaces and cylindrical outer surfaces of the first electrode SN. In an embodiment, the first electrode SN may have a semi-cylindrical shape. Specifically, the semi-cylindrical shape may refer to a structure in which the second electrode PN partially covers the outer surfaces of the first electrode SN.

In some embodiments, the first electrode SN may have a concave shape, a pillar shape, or a pylinder shape. The pylinder shape may refer to a structure in which a pillar shape and a cylindrical shape are merged.

The first electrode SN and the second electrode PN may include metal, noble metal, metal nitride, conductive metal oxide, conductive noble metal oxide, metal carbide, metal silicide, or a combination thereof. For example, the first electrode SN and the second electrode PN may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, a titanium silicon nitride/titanium nitride/tungsten (TiSiN/TiN/W) stack, or a combination thereof. The second electrode PN may also include a combination of a metal-based material and a silicon-based material. For example, the second electrode PN may be a titanium nitride/silicon germanium/tungsten nitride (TiN/SiGe/WN) stack. In the titanium nitride/silicon germanium/tungsten nitride (TiN/SiGe/WN) stack, silicon germanium may be a gap-fill material that fills the inside of the first electrode SN, titanium nitride (TiN) may serve as the second electrode PN of the data storage element CAP, and tungsten nitride may be a low-resistance material. In some embodiments, the second electrode PN may include a titanium nitride/tungsten/polysilicon (TiN/W/Poly-Si) stack.

The dielectric layer DE may be referred to as a “capacitor dielectric layer” or a “memory layer”. The dielectric layer DE may include silicon oxide, silicon nitride, a high-k material, a perovskite material, or a combination thereof. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). In some embodiments, the dielectric layer DE may be formed of a composite layer including two or more layers of the above-described high-k material.

The dielectric layer DE may be formed of zirconium (Zr)-based oxide. The dielectric layer DE may have a stack structure containing zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked on zirconium oxide (ZrO₂). The ZAZ stack may have a structure in which zirconium oxide (ZrO₂), aluminum oxide (Al₂O₃) and zirconium oxide (ZrO₂) are sequentially stacked. Each of the ZA stack and the ZAZ stack may be referred to as a “zirconium oxide (ZrO₂)-based layer”. In some embodiments, the dielectric layer DE may be formed of hafnium (Hf)-based oxide. The dielectric layer DE may have a stack structure containing hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked on hafnium oxide (HfO₂). The HAH stack may have a structure in which hafnium oxide (HfO₂), aluminum oxide (Al₂O₃) and hafnium oxide (HfO₂) are sequentially stacked. Each of the HA stack and the HAH stack may be referred to as a “hafnium oxide (HfO₂)-based layer”. In the ZA stack, ZAZ stack, HA stack and HAH stack, aluminum oxide (Al₂O₃) may have a greater band gap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high band gap material having a greater band gap energy than the high-k material. The dielectric layer DE may include silicon oxide (SiO₂) as a high band gap material other than aluminum oxide (Al₂O₃). Since the dielectric layer DE includes a high band gap material, leakage current may be suppressed. The high band gap material may be thinner than the high-k material. In some embodiments, the dielectric layer DE may include a stack structure in which a high-k material and a high band gap material are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, a HAHAH (HfO₂/Al₂O₃/HfO₂/Al₂O₃/HfO₂) stack a HZAZH(HfO₂/ZrO₂/Al₂O₃/ZrO₂/HfO₂) stack, a ZHZAZHZ(ZrO₂/HfO₂/ZrO₂/Al₂O₃/ZrO₂/HfO₂/ZrO₂) stack, a HZHZ(HfO₂/ZrO₂/HfO₂/ZrO₂) stack, or AHZAZHA(Al₂O₃/HfO₂/ZrO₂/Al₂O₃/ZrO₂/HfO₂/Al₂O₃) stack. In the above-described stack structures, aluminum oxide (Al₂O₃) may be thinner than zirconium oxide (ZrO₂) and hafnium oxide (HfO₂).

In some embodiments, the dielectric layer DE may include a high-k material and a high band gap material, and the dielectric layer DE may have a laminated structure in which a plurality of high-k materials and a plurality of high band gap materials are stacked, or an intermixed structure in which a high-k material and a high band gap material are intermixed.

In some embodiments, the dielectric layer DE may include a ferroelectric material, an anti-ferroelectric material, or a combination thereof. For example, the dielectric layer DE may include HfZrO.

In some embodiments, the dielectric layer DE may include a combination of a high-k material and a ferroelectric material, a combination of a high-k material and an anti-ferroelectric material, or a combination of a high-k material or a ferroelectric material and an anti-ferroelectric material.

In some embodiments, an interface control layer may be further formed between the first electrode SN and the dielectric layer DE to alleviate leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode PN and the dielectric layer DE.

The data storage element CAP may include a three-dimensional capacitor. The data storage element CAP may include a Metal-Insulator-Metal (MIM) capacitor. The data storage element CAP may be replaced with another data storage material. For example, the data storage material may be a thyristor, a phase-change material, a Magnetic Tunnel Junction (MTJ), or a variable resistance material.

The memory cell MC may further include a first contact node BLC and a second contact node SNC. The first contact node BLC may be disposed between the first conductive line BL and the nano sheet HL. The first contact node BLC may include a metal-based material or a semiconductive material. For example, the first contact node BLC may include titanium, titanium nitride, tungsten, or a combination thereof. In addition, the first contact node BLC may include doped polysilicon, and the first doped region SR may include an impurity diffused from the first contact node BLC. The second contact node SNC may be disposed between the nano sheet HL and the first electrode SN. The second contact node SNC may include a metal-based material or a semiconductive material. For example, the second contact node SNC may include titanium, titanium nitride, tungsten, or a combination thereof. In addition, the second contact node SNC may include doped silicon, and the second doped region DR may include an impurity diffused from the second contact node SNC. The height of the first contact node BLC in the first direction D1 may be less than that of the second contact node SNC in the first direction D1. The height of the first contact node BLC in the first direction DI may be greater than that of the channel CH in the first direction D1.

In some embodiments, the second contact node SNC may be selectively grown from the wide sheet WS of the nano sheet HL. The second contact node SNC may be formed by selective epitaxial growth (SEG). For example, the second contact node SNC may be a silicon epitaxial layer formed by the selective epitaxial growth (SEG). The second contact node SNC may be a doped silicon epitaxial layer.

In some embodiments, the first contact node BLC may be selectively grown from the narrow sheet NS of the nano sheet HL. The first contact node BLC may be formed by the selective epitaxial growth (SEG). For example, the first contact node BLC may be a silicon epitaxial layer formed by the selective epitaxial growth (SEG). The first contact node BLC may be a doped silicon epitaxial layer.

The first contact node BLC may be a narrow sheet-side contact node, and the second contact node SNC may be a wide sheet-side contact node.

The nano sheet HL may include a first edge and a second edge. The first edge may refer to a portion of the first doped region SR electrically coupled to the first conductive line BL, and the second edge may refer to a portion of the second doped region DR electrically coupled to the first electrode SN of the data storage element CAP.

The memory cell MC may further include an ohmic contact layer BLO between the first contact node BLC and the first conductive line BL. The ohmic contact layer BLO may include metal silicide. In some embodiments, the memory cell MC may further include an ohmic contact layer formed between the second contact node SNC and the first electrode SN of the data storage element CAP. The first conductive line BL, the ohmic contact layer BLO, the first contact node BLC and the first doped region SR may be electrically coupled to one another. The second doped region DR, the second contact node SNC and the first electrode SN of the data storage element CAP may be electrically coupled to one another.

The memory cell MC may further include a first spacer SP1 and a second spacer SP2. The first spacer SP1 may be disposed between the second conductive line WL and the second doped region DR. The second spacer SP2 may be disposed between the first conductive line BL and the second conductive line WL. The first and second spacers SP1 and SP2 may extend in the third direction D3 while surrounding the nano sheet HL. That is, the first and second spacers SP1 and SP2 may surround the nano sheet HL while being disposed on both sidewalls of the second conductive line WL.

The first spacer SP1 and the second spacer SP2 may have a double liner structure or a single liner structure. For example, the first spacer SP1 may have the single liner structure, the second spacer SP2 may have the double liner structure, and the double liner structure of the second spacer SP2 may include a stack of a first liner L1 and a second liner L2. The first and second spacers SP1 and SP2 may include a dielectric material. The first and second spacers SP1 and SP2 may include silicon oxide, silicon nitride, or a combination thereof. The first liner L1 of the second spacer SP2 may include silicon nitride, and the second liner L2 of the second spacer SP2 may include silicon oxide.

The first conductive line BL may include a plurality of horizontal extension portions BLE1, BLE2 and BLE3. The horizontal extension portions BLE1, BLE2 and BLE3 may extend in the second direction D2. The horizontal extension portions BLE1, BLE2 and BLE3 may include an inner horizontal extension portion BLE2 and outer horizontal extension portions BLE1 and BLE3. The inner horizontal extension portion BLE2 of the first conductive line BL may be disposed in a recess defined in the first liners L1 of the second spacers SP2 disposed vertically adjacent to each other. Accordingly, the inner horizontal extension portion BLE2 of the first conductive line BL may be electrically coupled to the ohmic contact layer BLO.

The outer horizontal extension portions BLE1 and BLE3 of the first conductive line BL may extend to be disposed in one side of the second spacer SP2. Accordingly, the outer horizontal extension portions BLE1 and BLE3 may contact the first and second liners L1 and L2 of the second spacer SP2. In some embodiments, the outer horizontal extension portions BLE1 and BLE3 of the first conductive line BL may be omitted.

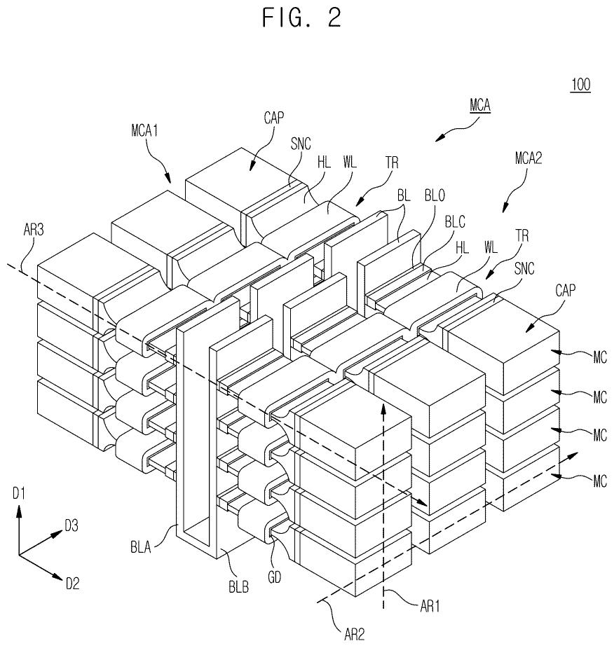

FIG. 2 is a schematic perspective view illustrating a semiconductor device 100 in accordance with an embodiment of the present disclosure.

Referring to FIG. 2, the semiconductor device 100 may include a memory cell array MCA. The memory cell array MCA may include a plurality of memory cells MC vertically stacked in a first direction D1. The memory cell array MCA may include the plurality of memory cells MC horizontally disposed in a second direction D2. The memory cell array MCA may include the plurality of memory cells MC horizontally disposed in a third direction D3.

Each of the memory cells MC may include a first conductive line BL, a switching element TR, and a data storage element CAP, and the switching element TR may include a second conductive line WL, a nano sheet dielectric layer GD, and a nano sheet HL. The memory cell MC may further include a first contact node BLC, an ohmic contact layer BLO, and a second contact node SNC. The memory cell MC may be the same as the memory cell MC illustrated in FIGS. 1A and 1B. As described with reference to FIGS. 1A and 1B, the second conductive line WL may have a gate all around (GAA) structure.

Although not illustrated, the memory cell MC may include a first spacer and a second spacer as described with reference to FIG. 1B. The first and second spacers may be disposed on both sides of the second conductive lines WL and extend in the third direction D3. The first and second spacers may extend in the third direction D3 while surrounding the nano sheets HL, similar to the second conductive lines WL.

The memory cell array MCA may include a column array ARI of the memory cells MC and a row array AR2 of the memory cells MC. The column array AR1 may include the plurality of memory cells MC vertically stacked in the first direction D1. The memory cells MC in the column array AR1 may share the first conductive line BL. The row array AR2 may include the plurality of memory cells MC horizontally disposed in the third direction D3. The memory cells MC in the row array AR2 may share the second conductive line WL. The second conductive lines WL of the memory cell array MCA may have a structure in which a plurality of surrounding bodies are mutually merged with a plurality of surrounding merge portions. Each of the surrounding merge portions may be disposed in a gap between the nano sheets HL in which the nano sheet dielectric layers GD are formed.

The column array AR1 may include a vertical arrangement of the nano sheets HL in the first direction D1, the first conductive line BL coupled in common to the nano sheets HL in the vertical arrangement, and the second conductive lines WL each surrounding a different one of the nano sheets HL in the vertical arrangement.

The row array AR2 may include a horizontal arrangement of the nano sheets HL in the third direction D3, the first conductive lines BL each coupled to a different one of the nano sheets HL in the horizontal arrangement, and the second conductive line WL surrounding the nano sheets HL in the horizontal arrangement.

The first direction D1 may be a vertical direction, and the third direction D3 may be a horizontal direction. The memory cell array MCA may further include a horizontal level array AR3, and the horizontal level array AR3 may include the plurality of memory cells MC disposed at the same horizontal level in the second direction D2. Neighboring memory cells MC in the horizontal level array AR3 may share the first conductive line BL.

The memory cell array MCA may include a first sub-cell array MCA1 and a second sub-cell array MCA2. The first sub-cell array MCA1 and the second sub-cell array MCA2 may each include a three-dimensional array of the memory cells MC. The first sub-cell array MCA1 and the second sub-cell array MCA2 may share the first conductive line BL. The first conductive line BL may include a first vertical conductive line BLA and a second vertical conductive line BLB, and a bottom portion of the first vertical conductive line BLA and a bottom portion of the second vertical conductive line BLB may be merged with each other. The first conductive line BL may have a U-shape by integration of the first vertical conductive line BLA and the second vertical conductive line BLB. The memory cells MC of the first sub-cell array MCA1 may share the first vertical conductive line BLA, and the memory cells MC of the second sub-cell array MCA2 may share the second vertical conductive line BLB. In this way, the neighboring first and second sub-cell arrays MCA1 and MCA2 may have a mirror-shaped structure of sharing the first conductive line BL. From a top view perspective, the first and second vertical conductive lines BLA and BLB may have a rectangular shape.

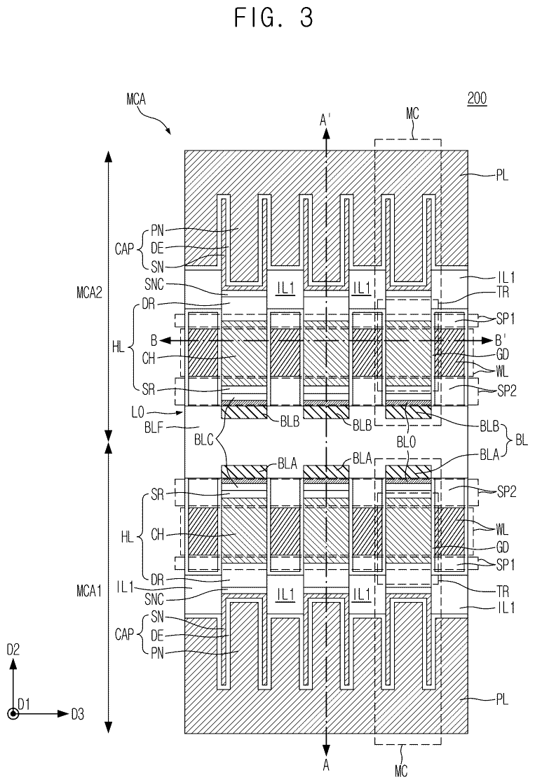

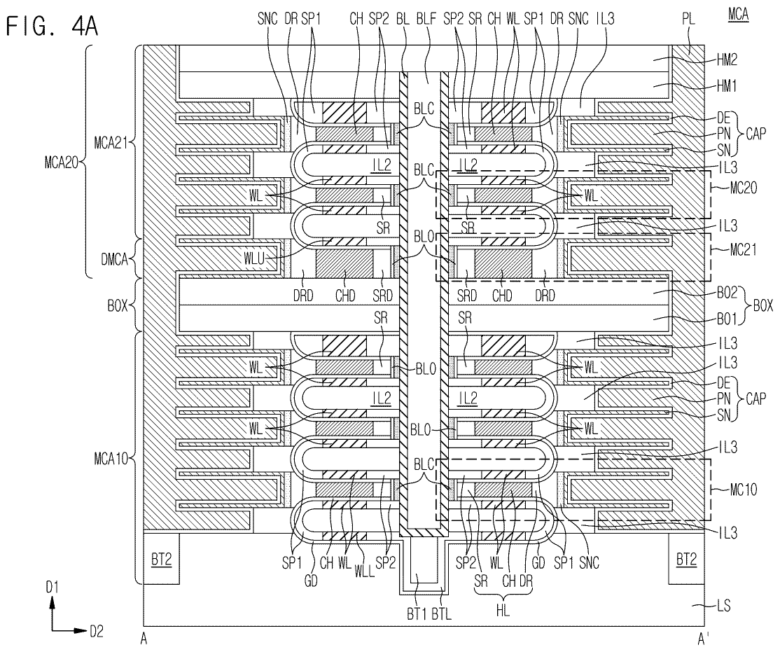

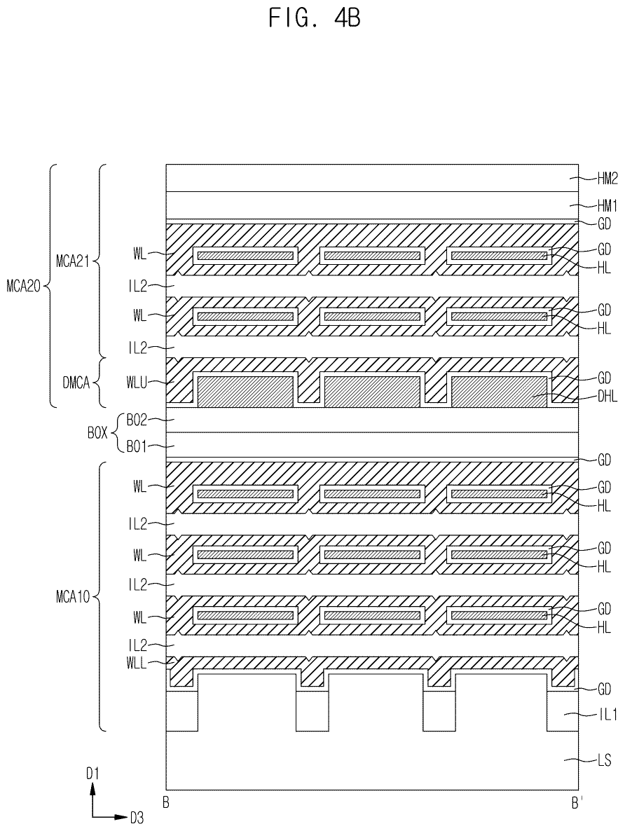

FIG. 3 is a schematic plan view illustrating a semiconductor device 200 in accordance with an embodiment of the present disclosure. FIG. 4A is a cross-sectional view of the semiconductor device 200 taken along line A-A′ illustrated in FIG. 3. FIG. 4B is a cross-sectional view of the semiconductor device 200 taken along line B-B′ illustrated in FIG. 3.

A memory cell array MCA of the semiconductor device 200 illustrated in FIGS. 3 to 4B may be similar to the memory cell array MCA illustrated in FIG. 2, and memory cells MC of the memory cell array MCA may be similar to the memory cell MC illustrated in FIGS. 1A and 1B. Hereinafter, detailed descriptions of overlapping components are provided above with reference to FIGS. 1A, 1B and 2.

Referring to FIGS. 3, 4A and 4B, the semiconductor device 200 may include the memory cell array MCA over a lower structure LS. The memory cell array MCA may include a lower-level array stack MCA10, an upper-level array stack MCA20, and a bonding structure BOX. The upper-level array stack MCA20 may include a first array stack MCA21 and a second array stack DMCA. The second array stack DMCA may be disposed between the first array stack MCA21 and the lower-level array stack MCA10. The second array stack DMCA and the bonding structure BOX may contact each other. The second array stack DMCA may also refer to bottom portions of the upper-level array stack MCA20.

The bonding structure BOX may be disposed between the upper-level array stack MCA20 and the lower-level array stack MCA10. The upper-level array stack MCA20 and the lower-level array stack MCA10 may be bonded to each other by the bonding structure BOX. The bonding structure BOX may include a stack of a first bonding layer BO1 and a second bonding layer BO2. The first bonding layer BO1 and the second bonding layer BO2 may be bonded by a wafer bonding process. The first bonding layer BO1 may be disposed on the lower-level array stack MCA10, and the second bonding layer BO2 may be disposed below the upper-level array stack MCA20. The first and second bonding layers BO1 and BO2 may include SiO₂, SiN, SiCN, SiCO, SiCON, or a combination thereof.

The lower-level array stack MCA10 and the upper-level array stack MCA20 may each include a three-dimensional array of the memory cells MC. The three-dimensional array of the memory cells MC may include a column array of the memory cells MC and a row array of the memory cells MC. The column array of the memory cells MC may include a plurality of memory cells MC stacked in a first direction D1, and the row array of the memory cells MC may include a plurality of memory cells MC horizontally disposed in a second direction D2. The row array of the memory cells MC may include a plurality of memory cells MC horizontally disposed in a third direction D3. The lower-level array stack MCA10 and the upper-level array stack MCA20 may each include sub-memory cell arrays disposed adjacent to each other in the second direction D2. Each of the sub-memory cell arrays may have a mirror-shaped structure in which two memory cells MC share a common plate PL. In some embodiments, the lower-level array stack MCA10 and the upper-level array stack MCA20 of the semiconductor device 200 may further include sub-memory cell arrays having a mirror-shaped structure in which two memory cells MC share a first conductive line BL. When the column array of the memory cells MC is repeated in the third direction D3, the row array of the memory cells MC may be configured.

The memory cells MC of the memory cell array MCA may include first memory cells MC10, second memory cells MC20, and third memory cells MC21. The first memory cells MC10 and the second memory cells MC20 may have the same components. The third memory cells MC21 may have similar configurations to the first and second memory cells MC10 and MC20.

Referring back to FIG. 4A, the lower-level array stack MCA10 may include a three-dimensional array of the first memory cells MC10, and the first array stack MCA21 of the upper-level array stack MCA20 may include a three-dimensional array of the second memory cells MC20. The second array stack DMCA of the upper-level array stack MCA20 may include the third memory cells MC21.

The second array stack DMCA of the upper-level array stack MCA20 may have a shorter height than the first array stack MCA21. A quantity of the second memory cells MC20 of the first array stack MCA21 may be greater than a quantity of the third memory cells MC21 of the second array stack DMCA. The second memory cells MC20 of the first array stack MCA21 and the third memory cells MC21 of the second array stack DMCA may have different shapes.

Each of the memory cells MC10 and MC20 may include a first conductive line BL, a switching element TR, and a data storage element CAP. The switching element TR may include a second conductive line WL, a nano sheet dielectric layer GD, and a nano sheet HL. Each of the first and second memory cells MC10 and MC20 may further include a first contact node BLC, an ohmic contact layer BLO, and a second contact node SNC. Each of the memory cells MC10 and MC20 may include first and second spacers SP1 and SP2. The first and second spacers SP1 and SP2 may be disposed on both sides of each of the second conductive lines WL. The first and second spacers SP1 and SP2 may extend in the third direction D3 while surrounding the nano sheets HL, similar to the second conductive lines WL.

Upper and the lower surfaces of each of the second conductive lines WL of the lower-level array stack MCA10 and the upper-level array stack MCA20 may include a plurality of shallow concaves. That is, the upper and lower surfaces of the second conductive lines WL may not have flat shapes but may have non-flat shapes due to the plurality of shallow concaves.

The lower-level array stack MCA10 may include first inter-cell dielectric layers IL1 disposed between the first memory cells MC10 disposed in the third direction D3. The lower-level array stack MCA10 may include second inter-cell dielectric layers IL2 disposed between the first memory cells MC10 stacked in the first direction D1. The upper-level array stack MCA20 may include first inter-cell dielectric layers IL1 disposed between the second memory cells MC20 disposed in the third direction D3. The upper-level array stack MCA20 may include second inter-cell dielectric layers IL2 disposed between the second memory cells MC20 stacked in the first direction D1.

The first inter-cell dielectric layers IL1 may be disposed between the data storage elements CAP in the third direction D3. The second inter-cell dielectric layers IL2 may be disposed between the second conductive lines WL in the first direction D1. The second inter-cell dielectric layers IL2 may each include a plurality of convexities. The convexities of the second inter-cell dielectric layers IL2 may be portions that fill the shallow concaves of the second conductive lines WL. Upper and lower surfaces of the second inter-cell dielectric layers IL2 may not have flat shapes but may have non-flat shapes due to the plurality of convexities. An uppermost second inter-cell dielectric layer IL2 and a lowermost second inter-cell dielectric layer IL2 among the second inter-cell dielectric layers IL2 may each include a combination of the flat shape and the non-flat shape.

Third inter-cell dielectric layers IL3 may be formed between the data storage elements CAP which are stacked in the first direction D1. The third inter-cell dielectric layers IL3 may include silicon oxide. The third inter-cell dielectric layers IL3 may be disposed between first electrodes SN of the data storage elements CAP in the first direction D1.

The first to third inter-cell dielectric layers IL1, IL2 and IL3 may each include silicon oxide, silicon carbon oxide, an air gap, an air gap-embedded oxide, or a combination thereof.

The first inter-cell dielectric layers ILI may be referred to as “vertical inter-cell dielectric layers”. The second inter-cell dielectric layers IL2 may be referred to as “first inter-cell horizontal dielectric layers”, and the third inter-cell dielectric layers IL3 may be referred to as “second inter-cell horizontal dielectric layers”.

The lower-level array stack MCA10 and the upper-level array stack MCA20 may each include a plurality of second conductive lines WL vertically stacked in the first direction D1. The lower-level array stack MCA10 and the upper-level array stack MCA20 may each include a plurality of nano sheets HL vertically stacked in the first direction D1. The lower-level array stack MCA10 and the upper-level array stack MCA20 may each include a plurality of data storage elements CAP vertically stacked in the first direction D1. The lower-level array stack MCA10 and the upper-level array stack MCA20 may each include a plurality of first conductive lines BL spaced apart in the third direction D3. The lower-level array stack MCA10 may include a lower-level horizontal electrode WLL, and the second array stack DMCA of the upper-level array stack MCA20 may include an upper-level horizontal electrode WLU. The upper-level horizontal electrode WLU and the lower-level horizontal electrode WLL may not surround the nano sheet HL. The upper-level horizontal electrode WLU and the lower-level horizontal electrode WLL may each have a non-surrounding shape. The second memory cells MC20 of the first array stack MCA21 may include the second conductive lines WL each having a gate all around (GAA) structure, and the third memory cells MC21 of the second array stack DMCA may include the upper-level horizontal electrode WLU having the non-surrounding shape.

A first bottom protective layer BT1 may be formed below the first conductive line BL, and a second bottom protective layer BT2 may be formed below the common plate PL. The first and second bottom protective layers BT1 and BT2 may each include silicon oxide, silicon nitride, silicon carbon oxide, or a combination thereof. A bottom liner BTL and the nano sheet dielectric layer GD may be formed between the first bottom protective layer BT1 and the lower structure LS.

A plurality of hard mask layers HM1 and HM2 may be disposed over an uppermost second conductive line WL.

The first spacer SP1 may be disposed between the second conductive line WL and the first electrode SN of the data storage element. The second spacer SP2 may be disposed between the second conductive line WL and the first conductive line BL. The second spacer SP2 may be disposed on an upper surface and a lower surface of each of the second inter-cell dielectric layers IL2. The first spacer SP1 may be formed on a first side of the second conductive line WL, and the second spacer SP2 may be formed on a second side of the second conductive line WL. The first spacer SP1 may cover one side of the second inter-cell dielectric layer IL2. One side of the second inter-cell dielectric layer IL2 may have a sphere-like shape, and the first spacer SPI may have a cup shape, for example, a ⊃ shape. The first spacer SPI may cover the sphere-like shape of the second inter-cell dielectric layer IL2.

The first spacer SP1 may be disposed between the second conductive line WL and a second doped region DR. The second spacer SP2 may be disposed between the first conductive line BL and the second conductive line WL. The first spacer SP1 and the second spacer SP2 may extend in the third direction D3 while surrounding the nano sheet HL. That is, the first and second spacers SP1 and SP2 may be disposed on both sidewalls of the second conductive line WL and surround the nano sheet HL.

The first spacer SP1 and the second spacer SP2 may each have a double liner structure or a single liner structure. For example, the first spacer SP1 may have the single liner structure, and the second spacer SP2 may have the double liner structure. The double liner structure of the second spacer SP2 may include the first liner L1 and the second liner L2 of FIG. 1B. The first and second spacers SP1 and SP2 may each include a dielectric material. The first and second spacers SP1 and SP2 may include silicon oxide, silicon nitride, silicon carbon oxide, an air gap, or a combination thereof.

The nano sheets HL of the switching elements TR horizontally disposed in the third direction D3 may share one second conductive line WL. The nano sheets HL of the switching elements TR horizontally disposed in the third direction D3 may be coupled to different first conductive lines BL. The switching elements TR stacked in the first direction D1 may share one first conductive line BL. The switching elements TR horizontally disposed in the third direction D3 may share one second conductive line WL.

The third inter-cell dielectric layers IL3 may be disposed between the first electrodes SN of the data storage elements CAP in the third direction D3. The first electrodes SN stacked in the first direction D1 may be isolated from one another by the third inter-cell dielectric layers IL3. Second electrodes PN of the data storage elements CAP may be coupled to the common plate PL. The lower-level array stack MCA10 and the upper-level array stack MCA20 may share the common plate PL.

The third memory cells MC21 of the second array stack DMCA of the upper-level array stack MCA20 may be referred to as “dummy cells”. The third memory cells MC21 of the second array stack DMCA may each include the upper-level horizontal electrode WLU having a single structure. The third memory cells MC21 of the second array stack DMCA may each include a horizontal arrangement of a bottom first doped region SRD, a bottom channel CHD and a bottom second doped region DRD. The horizontal arrangement of the bottom first doped region SRD, the bottom channel CHD and the bottom second doped region DRD may form a bottom sheet DHL of the upper-level array stack MCA20. A vertical height or thickness of the bottom sheet DHL may be greater than a vertical height or thickness of each of the nano sheets HL. The bottom first doped region SRD may be coupled to the first conductive line BL and the first contact node BLC, and the bottom second doped region DRD may be coupled to the second contact node SNC and the data storage element CAP.

In some embodiments, the second array stack DMCA may include a stack of the dummy cells.

In some embodiments, the second array stack DMCA may refer to a portion of the first array stack MCA21. In this case, the second memory cells MC20 of the first array stack MCA21 and the third memory cells MC21 of the second array stack DMCA may have the same configuration.

The lower-level array stack MCA10 and the upper-level array stack MCA20 may share the first conductive line BL and the common plate PL.

The lower structure LS may be disposed at a level lower than the memory cell array MCA. The lower structure LS may be made of any material suitable for semiconductor processing. The lower structure LS may include at least one of a conductive material, a dielectric material, and a semiconductive material. Various materials may be formed over the lower structure LS.

In an embodiment, the lower structure LS may include a semiconductor substrate. The lower structure LS may be formed of a silicon-containing material. The lower structure LS may include silicon, monocrystalline silicon, polysilicon, amorphous silicon, silicon germanium, monocrystalline silicon germanium, polycrystalline silicon germanium, carbon-doped silicon, a combination thereof, or multi-layers thereof. The lower structure LS may include another semiconductor material, such as germanium. The lower structure LS may include a III/V-group semiconductor substrate, for example, a chemical compound semiconductor substrate such as gallium arsenide (GaAs). The lower structure LS may include a Silicon-On-Insulator (SOI) substrate. The lower structure LS may be referred to as a “base body”.

In some embodiments, the lower structure LS may include a metal wiring structure, a dielectric structure, a conductive structure, a bonding pad structure, another memory, or a peripheral circuit portion. For example, the lower structure LS may include a structure in which the peripheral circuit portion, the metal wiring structure and the bonding pad structure are sequentially stacked. The memory cell array MCA and the peripheral circuit portion of the lower structure LS may be bonded by wafer bonding. The wafer bonding may include pad bonding, hybrid bonding, oxide-to-oxide bonding, metal-to-metal bonding, or a combination thereof. The peripheral circuit portion of the lower structure LS may be disposed at a level lower than the memory cell array MCA. This may be referred to as a “PERI under cell (PUC) structure” or a “cell over PERI (COP) structure”.

The peripheral circuit portion of the lower structure LS may include at least one control circuit for driving the memory cell array MCA. At least one control circuit of the peripheral circuit portion may include an N-channel transistor, a P-channel transistor, a CMOS circuit, or a combination thereof. At least one control circuit of the peripheral circuit portion may include an address decoder circuit, a read circuit, or a write circuit. At least one control circuit of the peripheral circuit portion may include a planar channel transistor, a recess channel transistor, a buried gate transistor, or a fin channel transistor (FinFET).

For example, the peripheral circuit portion may include sub-word line drivers and a sense amplifier. The second conductive lines WL may be coupled to the sub-word line drivers. The first conductive line BL may be coupled to the sense amplifier.

In some embodiments, the lower structure LS may include a semiconductor substrate, and the memory cell array MCA may be disposed over the lower structure LS, and the peripheral circuit portion may be disposed over the memory cell array MCA. This may be referred to as a “PERI over cell (POC) structure” or a “cell under PERI (CUP) structure”.

In some embodiments, the memory cell array MCA may include DRAM, embedded DRAM, NAND, FeRAM, STTRAM, PCRAM, or ReRAM.

Referring back to FIG. 3, a supporter BLF may be formed between the first conductive lines BL. The supporter BLF may extend vertically in the first direction D1 and horizontally in the third direction D3. The first conductive lines BL disposed adjacent to each other in the second direction D2 may be isolated by the supporter BLF. The first conductive lines BL disposed adjacent to each other in the third direction D3 may be isolated by the supporter BLF and the second spacer SP2. The supporter BLF may include a dielectric material. The supporter BLF may include silicon oxide, silicon nitride, an air gap, or a combination thereof. The supporter BLF may be referred to as a “vertical dielectric layer”.

As described with reference to FIGS. 3 to 4B, the semiconductor device 200 may include a stack structure of the lower-level array stack MCA10, the bonding structure BOX and the upper-level array stack MCA20, and the lower-level array stack MCA10 and the upper-level array stack MCA20 may each include a three-dimensional array of the memory cells MC vertically stacked, and the three-dimensional array may include horizontally-oriented switching elements TR, vertically-oriented first conductive lines BL, and horizontally-oriented data storage elements CAP. The horizontally oriented switching elements TR may include the nano sheets HL and horizontally-oriented second conductive lines WL, and the nano sheets HL may include the first doped regions SR, the second doped regions DR, and channels CH between the first doped regions SR and the second doped regions DR. The horizontally-oriented second conductive lines WL may each have a gate all around (GAA) structure, and the gate all around (GAA) structure of the horizontally-oriented second conductive lines WL may surround all surfaces of the channels CH of the nano sheets HL. The horizontally-oriented second conductive lines WL may surround the channels CH of the nano sheets HL at the same horizontal level. The horizontally-oriented data storage elements CAP may include horizontally-oriented first electrodes SN, and the first electrodes SN may be electrically coupled to the second doped regions DR. The data storage elements CAP may further include the second electrodes PN and dielectric layers DE between the first electrodes SN and the second electrodes PN. The vertically-oriented first conductive lines BL may be electrically coupled to the first doped regions SR. The horizontally-oriented second conductive lines WL may be spaced apart from the channels CH by the nano sheet dielectric layers GD. The nano sheets HL may be horizontally formed in the vertical stack.

From another perspective, referring to FIG. 4B, the semiconductor device 200 may include a stack structure of the lower-level array stack MCA10, the bonding structure BOX and the upper-level array stack MCA20, and the lower-level array stack MCA10 and the upper-level array stack MCA20 may include a vertical stack in which the second inter-cell dielectric layers IL2 are alternately stacked with the nano sheets HL, the first conductive lines BL coupled to first edges of the nano sheets HL and vertically oriented in a stack direction of the vertical stack, i.e., the first direction D1, the second conductive lines WL including inner surfaces facing the nano sheets HL and outer surfaces facing the second inter-cell dielectric layers IL2 and horizontally oriented in a direction crossing the stack direction of the vertical stack, i.e., the third direction D3, the nano sheet dielectric layers GD formed between the inner surfaces of the second conductive lines WL and the nano sheets HL and formed between the outer surfaces of the second conductive lines WL and the second inter-cell dielectric layers IL2, and the data storage elements CAP each coupled to a different one of second edges of the nano sheets HL. The nano sheets HL may include the first doped regions SR, the second doped regions DR, and the channels CH between the first doped regions SR and the second doped regions DR. The second conductive lines WL may each have the gate all around (GAA) structure, and the gate all around (GAA) structure of the horizontally-oriented second conductive lines WL may surround all surfaces of the channels CH.

From another perspective, the semiconductor device 200 may include a stack structure of the lower-level array stack MCA10, the bonding structure BOX and the upper-level array stack MCA20, and the lower-level array stack MCA10 and the upper-level array stack MCA20 may each include a horizontal arrangement of the nano sheets HL and the second conductive line WL surrounding the horizontal arrangement of the nano sheets HL.

According to FIGS. 3 to 4B, the lower-level array stack MCA10 and the upper-level array stack MCA20 may be coupled to each other through the bonding structure BOX. A number of layers of the memory cells MC, MC10 and MC20 may be increased by the bonding structure BOX.

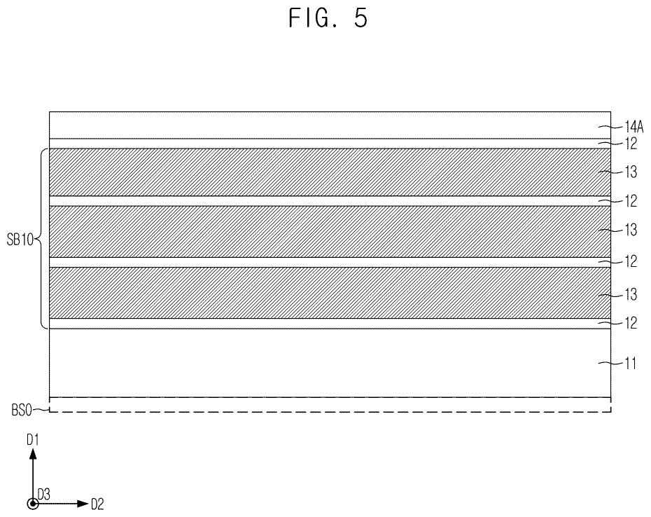

FIGS. 5 to 27 illustrate various views of a semiconductor device formed utilizing a method for fabricating the semiconductor device in accordance with an embodiment of the present disclosure. Hereinafter, a first direction, a second direction and a third direction in FIGS. 5 to 27 may correspond to the first direction D1, the second direction D2 and the third direction D3 described with reference to FIGS. 3 to 4B.

As illustrated in FIG. 5, a first mold stack SB10 may be formed on a substrate 11. The substrate 11 may be made of any material suitable for semiconductor processing. The substrate 11 may include at least one of a conductive material, a dielectric material, and a semiconductive material. The substrate 11 may include silicon, monocrystalline silicon, polysilicon, amorphous silicon, silicon germanium, monocrystalline silicon germanium, polycrystalline silicon germanium, carbon-doped silicon, a combination thereof, or multi-layers thereof. The substrate 11 may include another semiconductor material, such as germanium. The substrate 11 may include a III/V-group semiconductor substrate, for example, a chemical compound semiconductor substrate such as gallium arsenide (GaAs).

The first mold stack SB10 may include an alternating stack of first mold layers 12 and second mold layers 13. The first mold layers 12 may be alternately stacked with the second mold layers 13, and the first mold layers 12 and the second mold layers 13 may be epitaxially grown multiple times to form the first mold stack SB10.

The first mold layers 12 and the second mold layers 13 may be made of different semiconductive materials. The first mold layers 12 may include silicon germanium or monocrystalline silicon germanium. The second mold layers 13 may include monocrystalline silicon. The first mold layers 12 and the second mold layers 13 may be formed by an epitaxial growth process. A lowermost first mold layer 12 may serve as a seed layer during the epitaxial growth process. The first mold layers 12 may be thinner than the second mold layers 13. The first mold layers 12 may include first epitaxially grown layers, and the second mold layers 13 may include second epitaxially grown layers.

In an embodiment, a plurality of monocrystalline silicon germanium layers may be alternately stacked with a plurality of monocrystalline silicon layers in the first mold stack SB10. For example, the first mold layers 12 may be the monocrystalline silicon germanium layers, and the second mold layers 13 may be the monocrystalline silicon layers. A stack of a monocrystalline silicon germanium layer/a monocrystalline silicon layer (SiGe/Si stack) may be stacked multiple times. The first mold layers 12 may be referred to as “sacrificial layers”, and the second mold layers 13 may be referred to as “nano sheet target layers” or “recess target layers”.

The first mold stack SB10 may be referred to as a “vertical stack”. The first mold stack SB10 may be formed by alternately stacking a plurality of sacrificial layers and a plurality of nano sheet target layers. The sacrificial layers may be monocrystalline silicon germanium layers, and the nano sheet target layers may be monocrystalline silicon layers.

A thickness ratio of the first mold layers 12 and the second mold layers 13 in the first mold stack SB10 may vary based on design. For example, the thickness of each of the first mold layers 12 may be approximately 5 to 20 nm, and the thickness of each of the second mold layers 13 may be approximately 50 to 80 nm. A number of alterations of the first mold layers 12 and the second mold layers 13 in the first mold stack SB10 may vary based on design. In some embodiments, a triple stack including the first mold layer 12/the second mold layer 13/the first mold layer 12 may be defined at lowermost and/or uppermost portions of the first mold stack SB10. The second mold layer 13 of the triple stack may have a smaller thickness than the second mold layer 13 of the first mold stack SB10. An uppermost layer of the first mold stack SB10 may be the first mold layer 12.

The first mold stack SB10 may be replaced with the lower-level array stack MCA10 described with reference to FIG. 4A through a subsequent process.

A first bonding layer 14A may be formed on the first mold stack SB10. The first bonding layer 14A may include a dielectric material such as an oxide-based material, a nitride-based material, a carbon-based material, or a combination thereof. For example, the first bonding layer 14A may include SiO₂, SiN, SiCN, SiCO, SiCON, or a combination thereof. The first mold stack SB10, the substrate 11, and the first binding layer 14A may also be referred to as a first structure.

In some embodiments, a warpage prevention layer BSO may be formed on a back surface of the substrate 11. The warpage prevention layer BSO may be made of any material that is suitable for preventing warpage of the substrate 11 during a subsequent wafer bonding process. For example, the warpage prevention layer BSO may include silicon oxide. The warpage prevention layer BSO may control stress during the epitaxial growth of the first and second mold layers 12 and 13.

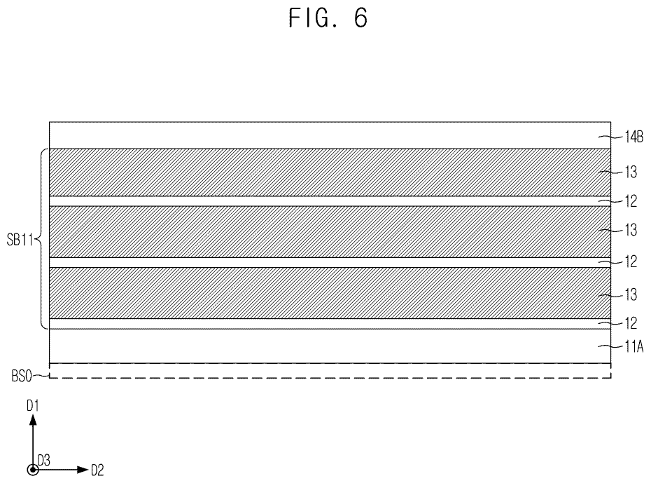

As illustrated in FIG. 6, a second mold stack SB11 may be formed on a sacrificial substrate 11A. The sacrificial substrate 11A may be made of any material suitable for semiconductor processing. The sacrificial substrate 11A may include at least one of a conductive material, a dielectric material, and a semiconductive material. The sacrificial substrate 11A may include silicon, monocrystalline silicon, polysilicon, amorphous silicon, silicon germanium, monocrystalline silicon germanium, polycrystalline silicon germanium, carbon-doped silicon, a combination thereof, or multi-layers thereof. The sacrificial substrate 11A may include another semiconductor material, such as germanium. The sacrificial substrate 11A may include a III/V-group semiconductor substrate, for example, a chemical compound semiconductor substrate such as gallium arsenide (GaAs). The sacrificial substrate 11A and the substrate 11 may be made of the same material. The sacrificial substrate 11A may be thinner than the substrate 11.

The second mold stack SB11 may include an alternating stack of first and second mold layers 12 and 13 as in the first mold stack SB10. The first and second mold layers 12 may be alternately stacked over the sacrificial substrate 11A. The first and second mold layers 12 and 13 may be epitaxially grown multiple times to form the second mold stack SB11. The first mold layers 12 and the second mold layers 13 may be made of different semiconductive materials. For example, in an embodiment, the first mold layers 12 may include silicon germanium or monocrystalline silicon germanium, while the second mold layers 13 may include monocrystalline silicon. The first and second mold layers 12 and 13 may be formed by an epitaxial growth process. An uppermost layer of the second mold stack SB11 may be one of the second mold layers 13. A thickness ratio of the first mold layers 12 and the second mold layers 13 in the second mold stack SB11 may vary based on design. For example, the thickness of each of the first mold layers 12 may be approximately 5 to 20 nm, and the thickness of each of the second mold layers 13 may be approximately 50 to 80 nm. A number of alterations of the first mold layers 12 and the second mold layers 13 in the second mold stack SB11 may vary based on design. In some embodiments, a triple stack including the first mold layer 12/the second mold layer 13/the first mold layer 12 may be defined at lowermost and/or uppermost portions of the second mold stack SB11. The second mold layer 13 of the triple stack may have a smaller thickness than the second mold layer 13 of the second mold stack SB11.

The second mold stack SB11 may be replaced with the upper-level array stack MCA20 described with reference to FIG. 4A through a subsequent process.

A second bonding layer 14B may be formed on the second mold stack SB11. The second bonding layer 14B may include a dielectric material such as an oxide-based material, a nitride-based material, a carbon-based material, or a combination thereof. The second mold stack SB11, the sacrificial substrate 11A, and the second bonding structure 14B may be referred to also as a second structure.

For example, the second bonding layer 14B may include SiO₂, SiN, SiCN, SiCO, SiCON, or a combination thereof. The first and second bonding layers 14A and 14B may be made of the same material. The first and second bonding layers 14A and 14B may have the same thickness. The first and second bonding layers 14A and 14B may be non-epitaxially grown materials. The first and second bonding layers 14A and 14B may be formed by a deposition process such as chemical vapor deposition (CVD) or atomic layer deposition (ALD).

In some embodiments, a warpage prevention layer BSO may be formed on a back surface of the sacrificial substrate 11A. The warpage prevention layer BSO may be a material for preventing warpage of the sacrificial substrate 11A during a subsequent wafer bonding process. The warpage prevention layer BSO may include silicon oxide. The warpage prevention layer BSO may also control stress during the epitaxial growth of the first and second mold layers 12 and 13.

According to FIGS. 5 and 6, the substrate 11 may be referred to as a “first wafer” or a “donor wafer”, and the sacrificial substrate 11A may be referred to as a “second wafer” or a “handle wafer.”

That is, the first mold stack SB10 may be formed on the first wafer, and the second mold stack SB11 may be formed on the second wafer.

When a plurality of silicon layers and a plurality of silicon germanium layers are alternately stacked and epitaxially grown to have no less than a specific thickness due to stress caused by lattice mismatch between a silicon layer and a silicon germanium layer, dislocation may occur in the alternating stack. The dislocation may deteriorate channel characteristics, thereby reducing reliability of memory cells.

Because the first and second mold stacks SB10 and SB11 are each formed on a different one of two wafers in an embodiment of the present disclosure, a stack structure having a higher stack density may be stably formed than when a mold stack is formed on a single wafer. In addition, because the first and second mold stacks SB10 and SB11 are each formed on a different one of two wafers, a dislocation-free epitaxial growth structure may be formed.

The first mold stack SB10 may have a “first dislocation-free epitaxial growth structure”, and the second mold stack SB11 may have a “second dislocation-free epitaxial growth structure”. Each of the first and second dislocation-free epitaxial growth structures may be a stack in which monocrystalline silicon layers and monocrystalline silicon germanium layers are alternately stacked and epitaxially grown.

In an embodiment, because a process of alternately stacking Si/SiGe stacks on two wafers, a process of forming bonding layers, and a process of performing wafer bonding are sequentially performed, it is possible to manufacture Si/SiGe alternating stacks with a high stack density without dislocation.

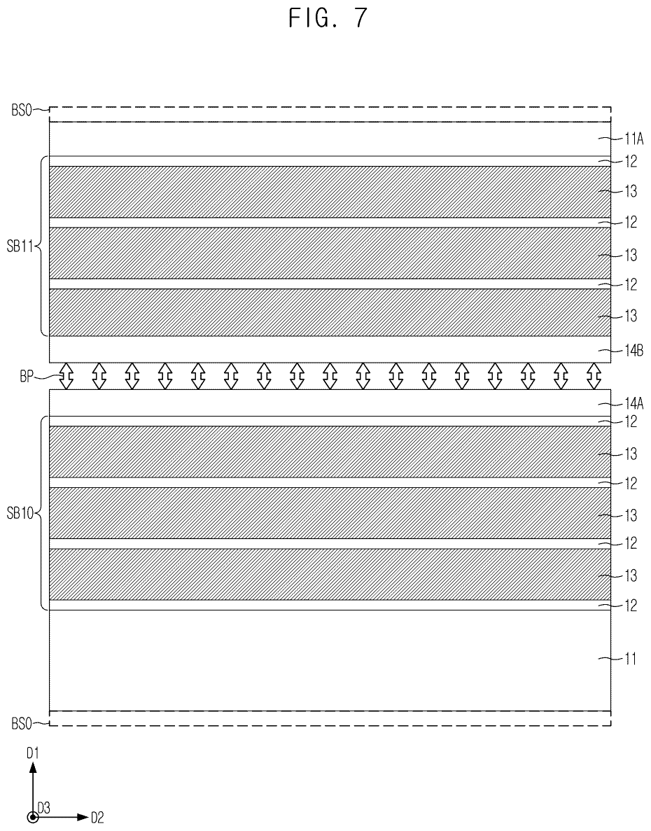

As illustrated in FIG. 7, the first bonding layer 14A and the second bonding layer 14B may be bonded to form a mold stack structure of a high stack including the first mold stack SB10 and the second mold stack SB11. For example, the sacrificial substrate 11A may be flipped so that the second bonding layer 14B is disposed at the bottom. The process of flipping the sacrificial substrate 11A on which the second bonding layer 14B is formed may be referred to as a “wafer flip” or a “substrate flip”. In an embodiment, the second structure may be flipped and positioned on the first structure so that the first and second bonding layers 14A and 14B are positioned adjacent to each other.

The first bonding layer 14A and the second bonding layer 14B may then be bonded together, for example, via any suitable wafer bonding process BP. For example, the first bonding layer 14A and the second bonding layer 14B may be bonded by oxide-to-oxide bonding. Also, as an example, the wafer bonding process BP may include fusion bonding. The fusion bonding may be referred to as “direct bonding”. The fusion bonding may use chemical bonding of the first bonding layer 14A and the second bonding layer 14B. Specifically, the first bonding layer 14A and the second bonding layer 14B may be fusion-bonded to provide a Si—O—Si bonding connection between the first mold stack SB1 and the second mold stack SB11.

In some embodiments, the warpage prevention layers BSO may prevent warpage of the sacrificial substrate 11A and the substrate 11 during the wafer bonding process BP.

Subsequently, edge trim may be performed on the substrate 11 and the sacrificial substrate 11A bonded by the wafer bonding process BP.

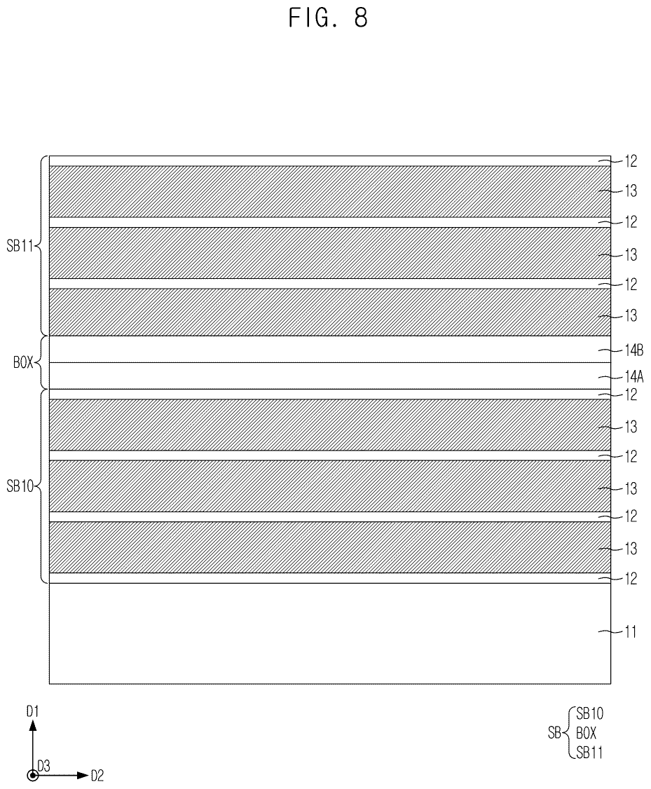

As illustrated in FIG. 8, the sacrificial substrate 11A may be removed. Removing the sacrificial substrate 11A may include grinding a portion of the sacrificial substrate 11A and performing a wet etch process on a remaining portion of the sacrificial substrate 11A. During the wet etch process, an uppermost first mold layer 12 of the second mold stack SB11 may serve as an etch stopper.

In some embodiments, before the sacrificial substrate 11A is removed, the warpage prevention layer BSO on the sacrificial substrate 11A may be removed. The warpage prevention layer BSO disposed on the back surface of the substrate 11 may be maintained during subsequent processes. Hereinafter, a reference symbol of the warpage prevention layer BSO disposed on the back surface of the substrate 11 is omitted.

According to FIGS. 7 and 8, as a result of performing the wafer bonding process BP, a mold stack SB may be formed on the substrate 11. The mold stack SB may include dislocation-free epitaxial growth structures and a bonding structure BOX. The dislocation-free epitaxial growth structures may include the first and second mold stacks SB10 and SB11, and the bonding structure BOX may include the first bonding layer 14A and the second bonding layer 14B.

The first mold stack SB10, the first bonding layer 14A, the second bonding layer 14B, the second mold stack SB11 and the sacrificial substrate 11A may be sequentially stacked on the substrate 11 by the wafer bonding process BP. The first mold stack SB10, the first bonding layer 14A, the second bonding layer 14B and the second mold stack SB11 may be one mold stack SB. The first mold stack SB10, the bonding structure BOX and the second mold stack SB11 may be sequentially stacked in the mold stack SB. The bonding structure BOX may be disposed between the first mold stack SB10 and the second mold stack SB11. Each of the first and second mold stacks SB10 and SB11 may include the plurality of first mold layers 12 and the plurality of second mold layers 13. An uppermost first mold layer 12 of the first mold stack SB10 and a lowermost second mold layer 13 of the second mold stack SB11 may directly contact the bonding structure BOX. The first mold stack SB10 and the second mold stack SB11 may be physically and/or chemically discontinuous by the bonding structure BOX.

The mold stack SB may include the dislocation-free epitaxial growth structures. The first mold stack SB10 may be the first dislocation-free epitaxial growth structure, and the second mold stack SB11 may be the second dislocation-free epitaxial growth structure. Each of the first and second dislocation-free epitaxial growth structures may be a stack in which monocrystalline silicon layers and monocrystalline silicon germanium layers are alternately stacked and epitaxially grown. That is, each of the first and second dislocation-free epitaxial growth structures may be referred to as a “Si/SiGe mold stack”.

The mold stack SB may include the plurality of first mold layers 12 and the plurality of second mold layers 13. The first bonding layer 14A and the second bonding layer 14B of the mold stack SB may serve to distribute stress between the first and second mold layers 12 and 13. The first and second bonding layers 14A and 14B may be referred to as “stress distributing layers”.

A thickness ratio of the first mold layers 12 and the second mold layers 13 in the mold stack SB may vary based on design. For example, the thickness of each of the first mold layers 12 may be approximately 10 nm, and the thickness of each of the second mold layers 13 may be approximately 70 nm. In some embodiments, the thickness of each of the first mold layers 12 may be approximately 15 nm, and the thickness of each of the second mold layers 13 may be approximately 65 nm.

The number of the first and second mold layers 12 and 13 in the first and second mold stacks SB10 and SB11 may vary based on design. When the wafer bonding process BP is applied, a critical thickness of the Si/SiGe stack of the mold stack SB may increase by approximately two times. For example, a number of layers, which makes it possible to be dislocation-free based on the Si/SiGe (70 nm/10 nm) stack, is 139 stacks, and the number of layers may be 278 stacks when the wafer bonding process BP is applied.

In some embodiments, a silicon germanium blocking layer may be formed in advance before the second mold stack SB11 is formed on the sacrificial substrate 11A. The silicon germanium blocking layer may be used as a blocking layer when the subsequent sacrificial substrate 11A is removed. A thickness of the silicon germanium blocking layer may be 10 nm to 30 nm.

In some embodiments, silicon oxide may be formed as the warpage prevention layers BSO to control stress during the epitaxial growth process for forming the first and second mold stacks SB10 and SB11. The silicon oxide of the warpage prevention layers BSO may be formed on the backsides of the substrate 11 and the sacrificial substrate 11A before or after the wafer bonding process BP.

According to FIGS. 5 to 8, a method for fabricating the semiconductor device according to an embodiment may include forming the first mold stack SB10 including the first and second mold layers 12 and 13 epitaxially grown on the substrate 11, forming the first bonding layer 14A on the first mold stack SB10, forming the second mold stack SB11 including the first and second mold layers 12 and 13 epitaxially grown on the sacrificial substrate 11A, forming the second bonding layer 14B on the second mold stack SB11, bonding the first bonding layer 14A and the second bonding layer 14B to form the mold stack SB with the high stack including the first mold stack SB10 and the second mold stack SB11, and removing the sacrificial substrate 11A. The mold stack SB with the high stack may include a high stack structure of the first mold layers 12 and the second mold layers 13.

Subsequently, a series of processes may be performed on the mold stack SB with the high stack to form a memory cell array MCA including memory cells MC with the high stack including the lower-level array stack and the upper-level array stack described with reference to FIGS. 2 to 4B. For example, the first mold stack SB10 may be replaced with the lower-level array stack MCA10, and the second mold stack SB11 may be replaced with the upper-level array stack MCA20. As will be described subsequently, the second mold layers 13 of the mold stack SB may become nano sheets each including a narrow sheet and a wide sheet by selective recessing processes. The first mold layers 12 of the mold stack SB may be removed.

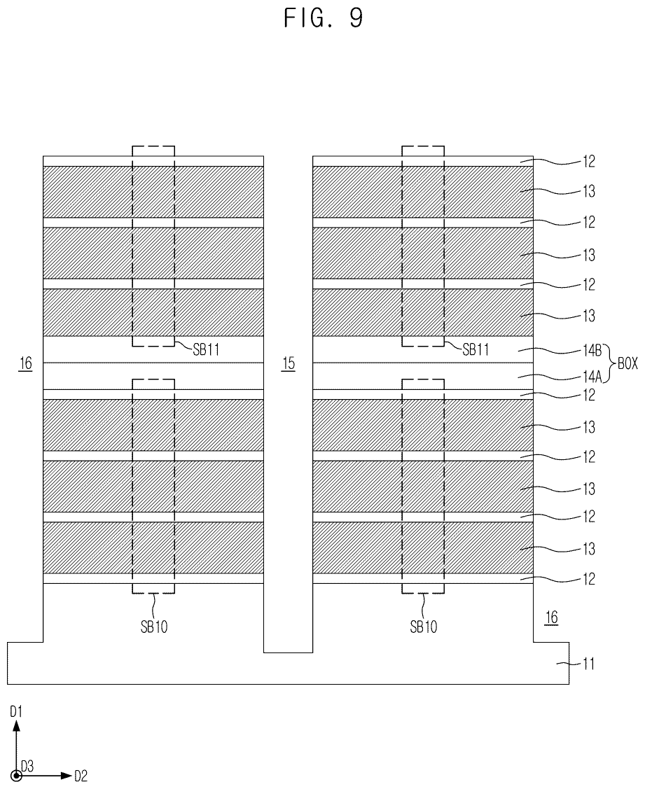

As illustrated in FIG. 9, a plurality of sacrificial linear openings 15 and 16 may be formed in the mold stack SB. The sacrificial linear openings 15 and 16 may include a first sacrificial linear opening 15 and a second sacrificial linear opening 16. From a top view perspective, the first and second sacrificial linear openings 15 and 16 may be line-shaped openings extending in the third direction D3.

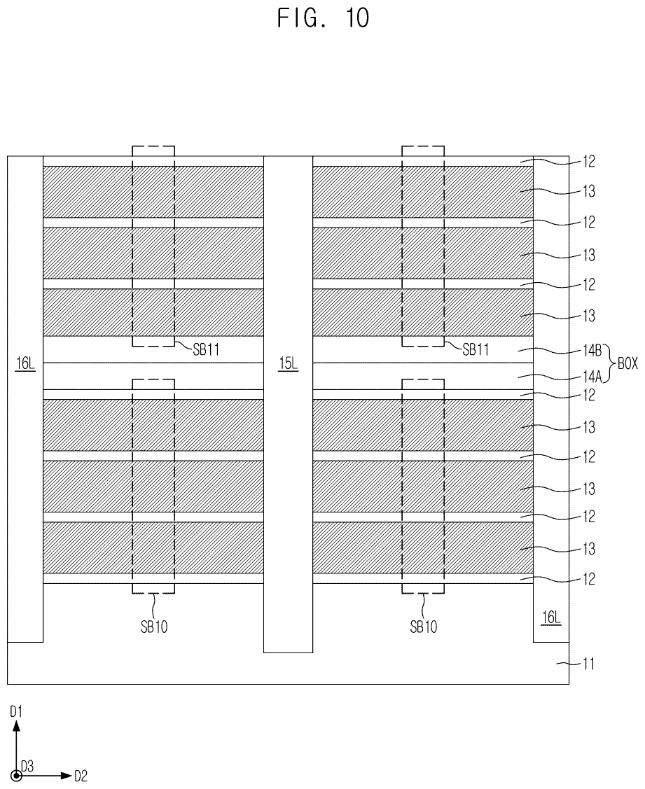

As illustrated in FIG. 10, linear sacrificial layers 15L and 16L may be formed to fill the first and second sacrificial linear openings 15 and 16, respectively. The linear sacrificial layers 15L and 16L may include first linear sacrificial layers 15L and second linear sacrificial layers 16L. From a top view perspective, the first and second linear sacrificial layers 15L and 16L may have line shapes extending in the third direction D3. The first and second linear sacrificial layers 15L and 16L may each extend vertically in the first direction D1. From a top view perspective, cross-sections of the first and second linear sacrificial layers 15L and 16L may each have a rectangular shape. In some embodiments, the cross-sections of the first and second linear sacrificial layers 15L and 16L may each have a circular shape or an oval shape. The first and second linear sacrificial layers 15L and 16L may be made of the same material. For example, the first and second linear sacrificial layers 15L and 16L may be formed of a dielectric material, such as, silicon oxide, silicon nitride, silicon carbon oxide, silicon carbon nitride, or a combination thereof.

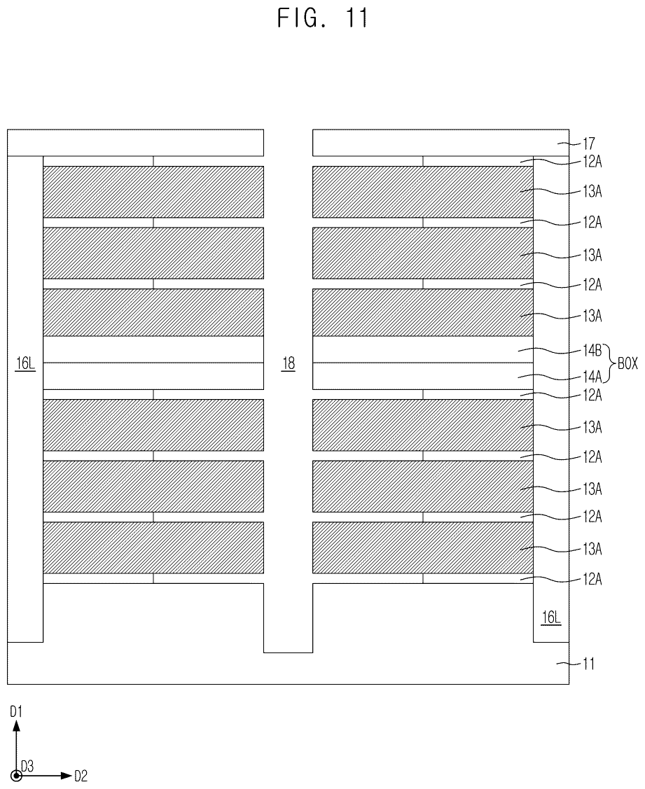

As illustrated in FIG. 11, among the first and second linear sacrificial layers 15L and 16L, the first linear sacrificial layer 15L may be selectively removed to form a first linear opening 18. A bottom portion of the first linear opening 18 may extend inside the substrate 11. From a top view perspective, the first linear opening 18 may have a line shape extending in the third direction D3 and be horizontally spaced apart at a regular interval from adjacent second linear sacrificial layers 16L in the second direction D2.

Subsequently, the first mold layers 12 may be selectively recessed through the first linear opening 18 leaving only a remaining portion 12A. To selectively recess the first mold layers 12, a difference in etch selectivity between the first mold layers 12 and the second mold layers 13 may be used. The first mold layers 12 may be removed using a wet etch process or a dry etch process. For example, when the first mold layers 12 include silicon germanium layers and the second mold layers 13 include monocrystalline silicon layers, the silicon germanium layers may be etched using an etchant or etch gas having a selectivity with respect to the monocrystalline silicon layers. The remaining portion 12A of the first mold layers 12 may each have an original thickness.

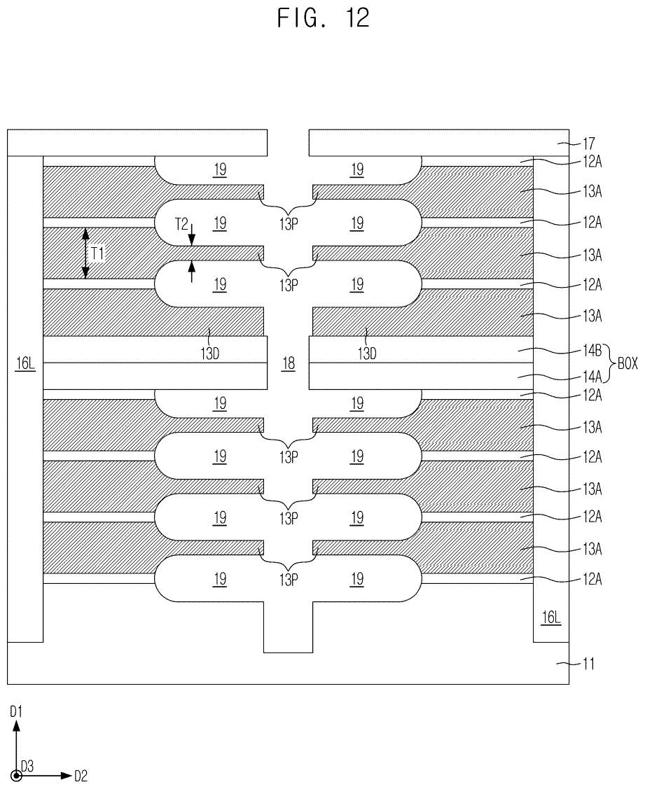

As illustrated in FIG. 12, a portion (a first portion) of each of the second mold layers 13 may be selectively recessed to form a narrow sheet 13P. The selective recessing of the second mold layers 13 may be performed in the second direction D2 from the first linear opening 18. A wet or dry etch process may be used to recess the second mold layer 13. An original body portion 13A and the narrow sheet 13P may be formed by the partial recessing of each of the second mold layers 13. The original body portion 13A may maintain an original thickness T1, and the narrow sheet 13P may have a thickness T2 less than the original thickness T1. A horizontal length of the original body portion 13A in the second direction D2 may be equal to or different from one of the narrow sheet 13P in the second direction D2. A combination of the original body portion 13A and the narrow sheet 13P may be referred to as a “preliminary nano sheet”. The narrow sheet 13P may be referred to as a “flat plate-shaped sheet” or a “protruding narrow sheet”. As above, the first portion of the second mold layer 13 may be selectively recessed and form the preliminary nano sheet including the original body portion 13A and the narrow sheet 13P.

A recess process for forming the narrow sheet 13P may be referred to as a “thinning process” or “trimming process” of the second mold layer 13. To form the narrow sheet 13P, an upper surface, lower surface and side surface of the second mold layer 13 may be recessed. The narrow sheet 13P may be referred to as a “thin-body active layer.” The narrow sheet 13P may include a monocrystalline silicon layer. The recess process for forming the narrow sheet 13P may use, for example, Hot SC-1 (HSC1). The HSC1 may include a solution in which ammonium hydroxide (NH₄OH), hydrogen peroxide (H₂O₂) and water (H₂O) are mixed in a ratio of 1:4:20. Using the HSC1, the second mold layer 13 may be selectively etched.

The narrow sheets 13P may be formed by the partial recess process for the second mold layers 13 as described above, and an inter-nano sheet recess 19 may be formed between the narrow sheets 13P that are vertically disposed. Upper and lower surfaces of the narrow sheets 13P may each include a flat surface. A boundary portion between the original body portion 13A and the narrow sheet 13P may be vertical or have a curvature. Each of the first mold layers 12A may be disposed between the original body portions 13A that are vertically stacked. Horizontal arrangements of the narrow sheets 13P may be formed in the third direction D3. Vertical arrangements of the narrow sheets 13P may be formed in the first direction D1. The inter-nano sheet recesses 19 may be referred to as a “vertical gaps” between the narrow sheets 13P in the vertical arrangement.

Among the narrow sheets 13P, a narrow sheet over the bonding structure BOX, i.e., a bottom sheet 13D, may be thicker than the other narrow sheets 13P.

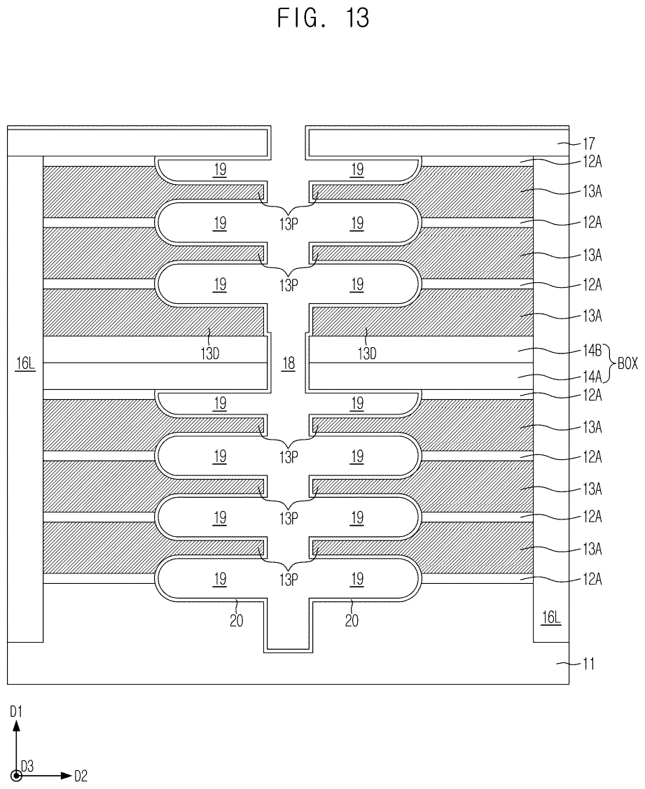

As illustrated in FIG. 13, a nano sheet dielectric layer 20 may be formed on the exposed portions of the narrow sheets 13P. The nano sheet dielectric layer 20 may serve as a “gate dielectric layer.”

The nano sheet dielectric layer 20 may be formed by oxidizing surfaces of the narrow sheets 13P. In some embodiments, the nano sheet dielectric layer 20 may be formed by a process of depositing silicon oxide and a process of oxidizing the surfaces of the narrow sheets 13P. The nano sheet dielectric layer 20 may include silicon oxide, silicon nitride, metal oxide, metal oxide nitride, metal silicate, a high-k material, a ferroelectric material, an anti-ferroelectric material, or a combination thereof. The nano sheet dielectric layer 20 may include SiO₂, Si₃N₄, HfO₂, Al₂O₃, ZrO₂, AlON, HfON, HfSiO, HfSiON, or a combination thereof. The nano sheet dielectric layer 20 may be conformally formed on the surfaces of the narrow sheets 13P. The nano sheet dielectric layer 20 may extend to be formed on exposed surfaces of the first mold layers 12A and the original body portions 13A. The nano sheet dielectric layer 20 may be formed on the exposed surfaces of the substrate 11 and the bottom sheet 13D. The nano sheet dielectric layer 20 may be formed on a portion of the first bonding layer 14A and a portion of the second bonding layer 14B of the bonding structure BOX.

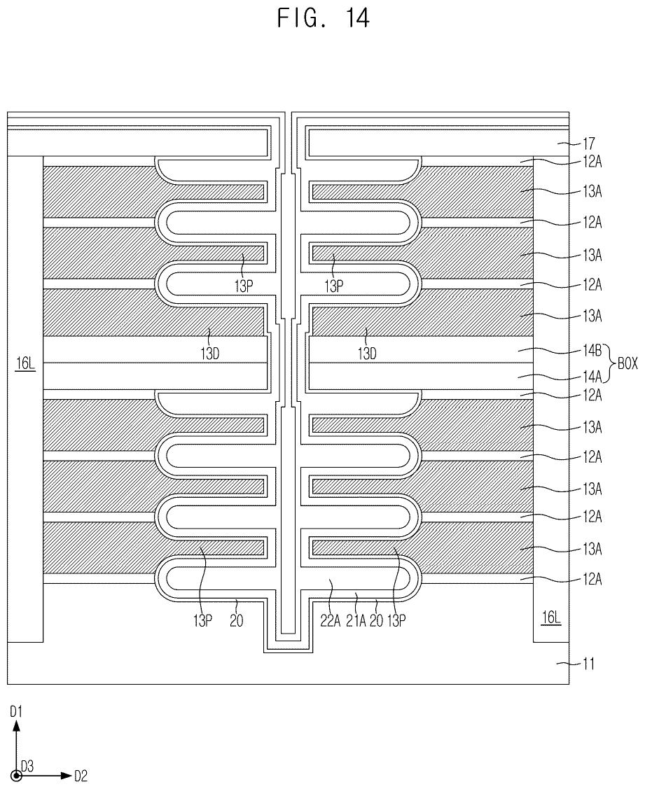

As illustrated in FIG. 14, a first spacer layer 21A may be formed on the nano sheet dielectric layer 20. The first spacer layer 21A may include silicon nitride. The first spacer layer 21A may surround and cover the narrow sheets 13P on the nano sheet dielectric layer 20. The first spacer layer 21A may be thicker than the nano sheet dielectric layer 20.

A first inter-cell horizontal dielectric material 22A may be formed on the first spacer layer 21A. The first inter-cell horizontal dielectric material 22A may include silicon oxide. The first spacer layer 21A and the first inter-cell horizontal dielectric material 22A may fill the inter-nano sheet recesses 19 between the nano sheets 13P. The first spacer layer 21A and the first inter-cell horizontal dielectric material 22A may partially fill the first linear opening 18.

As illustrated in FIG. 15, a portion of the first inter-cell horizontal dielectric material 22A may be cut through the first linear opening 18. Accordingly, the first inter-cell horizontal dielectric material may remain as a plurality of first inter-cell horizontal dielectric layers 22 as indicated by reference numeral “22”.

Subsequently, the first spacer layer 21A may be selectively recessed through the first linear opening 18 to form a first spacer 21. As the first spacer 21 is formed, linear surrounding recesses 23 surrounding the narrow sheets 13P may be formed on the nano sheet dielectric layer 20. Each of the first inter-cell horizontal dielectric layers 22 may be disposed between the linear surrounding recesses 23 vertically disposed. The first spacer 21 may surround the narrow sheets 13P at the same horizontal level in the third direction D3.

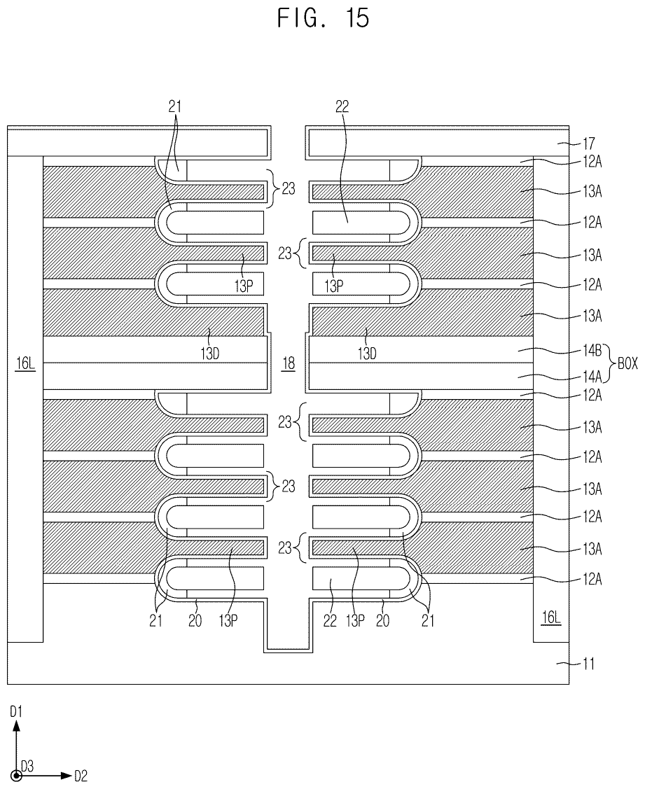

As illustrated in FIG. 16, horizontal conductive lines 24 may be formed to fill the linear surrounding recesses 23. The horizontal conductive lines 24 may horizontally extend in the third direction D3. The horizontal conductive lines 24 may correspond to the second conductive lines WL described with reference to FIGS. 2 to 4B.

Forming the horizontal conductive lines 24 may include depositing a conductive material filling the linear surrounding recesses 23 on the nano sheet dielectric layer 20 and performing a horizontal etch-back process on the conductive material. The horizontal etch-back process on the conductive material may be performed in the second direction D2 from the first linear opening 18. The horizontal conductive lines 24 may simultaneously surround the narrow sheets 13P at the same horizontal level. The horizontal conductive lines 24 may include metal, a metal-based material, a semiconductive material, or a combination thereof.

The horizontal conductive lines 24 may include molybdenum, molybdenum nitride, ruthenium, titanium nitride, tungsten, polysilicon, or a combination thereof. For example, the horizontal conductive lines 24 may include a TiN/W stack in which titanium nitride and tungsten are sequentially stacked. The horizontal conductive lines 24 may include an N-type work function material or a P-type work function material. The N-type work function material may have a low work function of 4.5 eV or lower, and the P-type work function material may have a high work function of 4.5 eV or higher. Each of the first inter-cell horizontal dielectric layers 22 may be disposed between a plurality of horizontal conductive lines 24 in the first direction D1. The horizontal conductive lines 24 surrounding the narrow sheets 13P may be referred to as “gate-all-around (GAA) electrodes”. The narrow sheets 13P may be referred to as “nano sheet channels”, “nano wires”, or “nano wire channels”.

A lower-level horizontal electrode 24L may be formed on the surface of the substrate 11. An upper-level horizontal electrode 24U may be formed over the bottom sheet 13D. The lower-level and upper-level horizontal electrodes 24L and 24U may each have a non-surrounding shape.

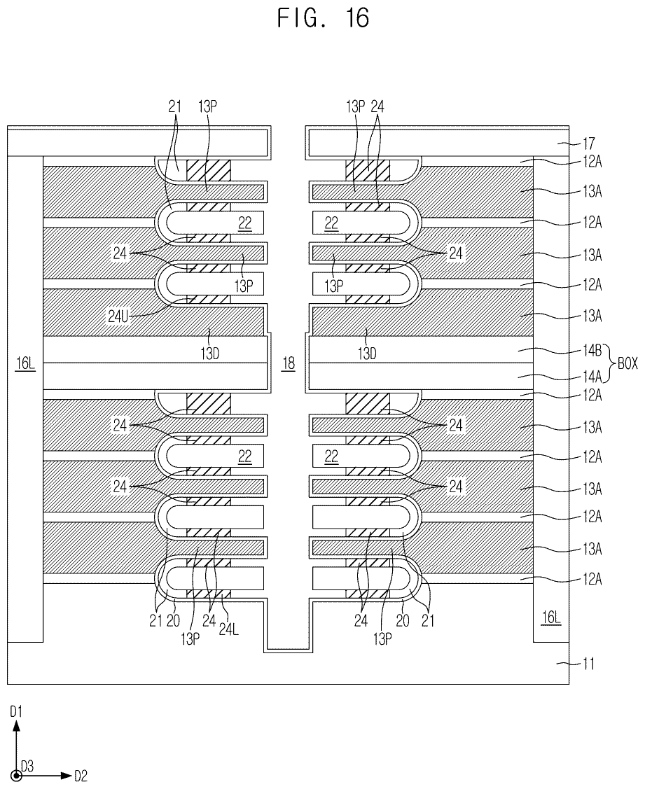

As illustrated in FIG. 17, a second spacer 25 may be formed on a side surface of each of the horizontal conductive lines 24. The second spacer 25 may be formed by depositing and etching a spacer material. The etching of the spacer material may include an etch-back process. The etch-back process of the spacer material may be performed in the second direction D2 from the first linear opening 18. The second spacer 25 may include silicon oxide, silicon nitride, silicon carbon oxide, an embedded air gap, or a combination thereof. A bottom liner 25D may be formed on a side surface of the lower-level horizontal electrode 24L while or after the second spacer 25 is formed. The bottom liner 25D and the second spacer 25 may be made of the same material. The second spacer 25 may extend in the third direction D3. The second spacer 25 may surround the narrow sheets 13P at the same horizontal level disposed in the third direction D3.

Subsequently, deposition and etch-back processes of a first bottom protective layer 26 may be performed. The first bottom protective layer 26 may include a dielectric material such as Spin On Dielectric (SOD). The first bottom protective layer 26 may include silicon oxide, silicon nitride, silicon carbon oxide, or a combination thereof.

After the first bottom protective layer 26 is formed, a portion of the nano sheet dielectric layer 20 may be cut to expose one side of each of the narrow sheets 13P.

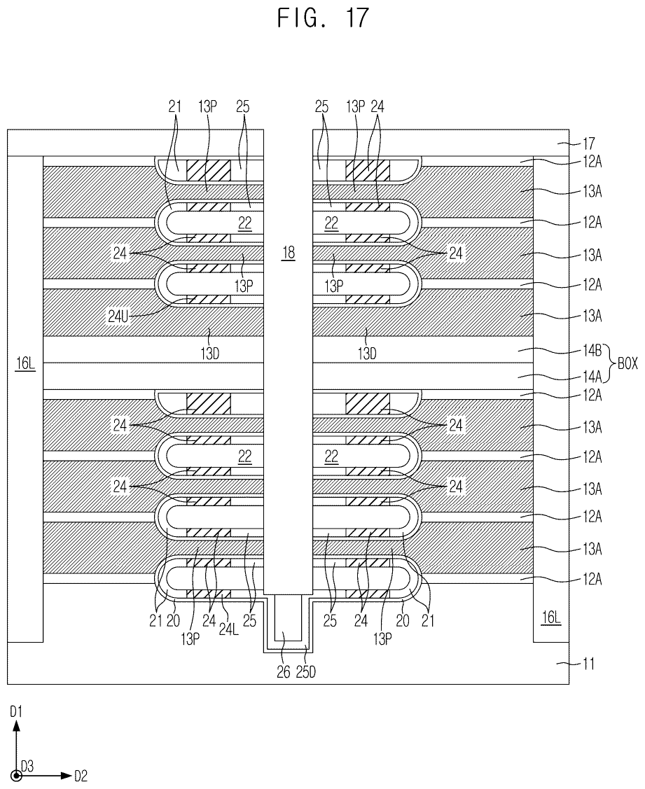

As illustrated in FIG. 18, one side of each of the narrow sheets 13P and a portion of the nano sheet dielectric layer 20 may be horizontally recessed in the second direction D2 to form nano sheet level recesses 27 by the recessing of the narrow sheets 13P. The nano sheet level recesses 27 may be side-recesses disposed in the second spacers 25.

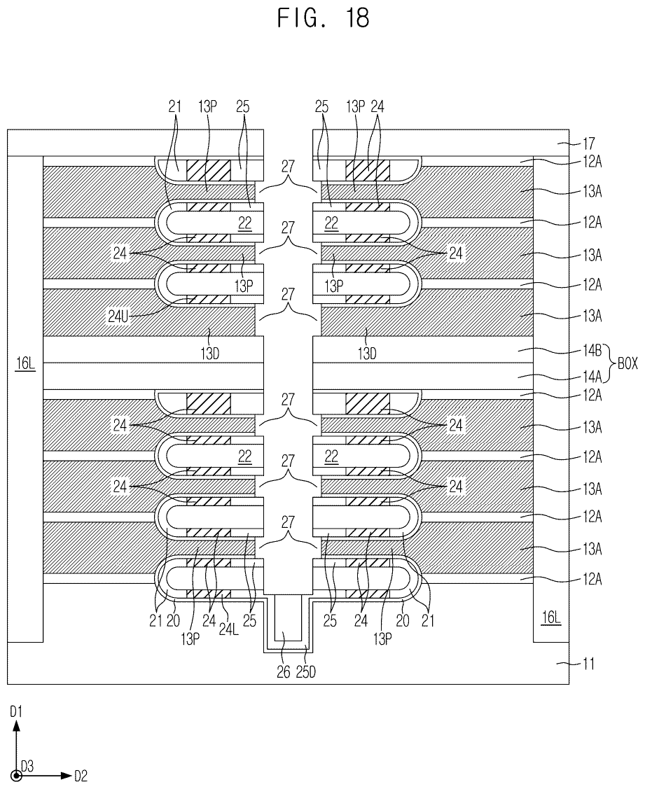

As illustrated in FIG. 19, first contact nodes 28 filling the nano sheet level recesses 27 may be formed. Forming the first contact nodes 28 may include depositing a conductive material filling the nano sheet level recesses 27 and performing an etch-back process on the conductive material. The first contact nodes 28 may include a semiconductive material. The first contact nodes 28 may include doped polysilicon with N-type dopants. The first contact nodes 28 may fill the nano sheet level recesses 27 formed between the second spacers 25.

A first doped region 29 may be formed in one side of each of the narrow sheets 13P. A heat treatment process may be performed to form the first doped regions 29 by diffusing dopants from the first contact nodes 28. While the first doped regions 29 are formed, bottom first doped regions 29D may be formed in the bottom sheets 13D.

Another method of forming the first contact nodes 28 may include selective epitaxial growth (SEG) of a doped semiconductor material.

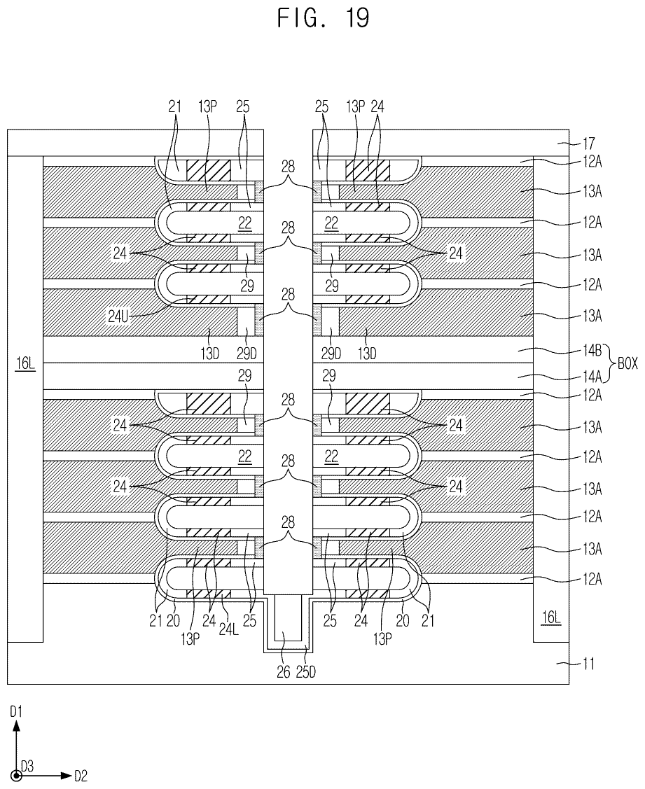

As illustrated in FIG. 20, a vertical conductive line 30 may be formed on the first contact nodes 28. Before the vertical conductive line 30 is formed, ohmic contact layers may be formed on the first contact nodes 28. The ohmic contact layers are described with reference to the ohmic contact layers BLO illustrated in FIGS. 1A and 1B.

The vertical conductive line 30 may be coupled in common to the narrow sheets 13P vertically disposed and the first contact nodes 28. The vertical conductive line 30 may correspond to the first conductive line BL illustrated in FIGS. 1A, 1B, 2, 3 and 4A. The vertical conductive line 30 may include a plurality of horizontal extension portions BLE1, BLE2 and BLE3 described with reference to FIGS. 1A and 1B.

The vertical conductive line 30 may include a metal-based material. The vertical conductive line 30 may include titanium nitride, tungsten, or a combination thereof.

Forming the vertical conductive line 30 may include deposition and etch processes of a vertical conductive line material. The vertical conductive line 30 may vertically extend in the first direction D1. The vertical conductive lines 30 disposed adjacent to each other in the second direction D2 may be coupled to each other. That is, the narrow sheets 13P disposed adjacent to each other in the second direction D2 may share the vertical conductive line 30. The vertical conductive line 30 may have a U shape.

A supporter 31 or a supporter layer may be formed on the vertical conductive line 30. The supporter 31 may extend vertically in the first direction D1 and horizontally in the third direction D3. The vertical conductive lines 30 disposed adjacent to each other in the third direction D3 may be isolated by the supporter 31. The supporter 31 may include a dielectric material. The supporter 31 may include silicon oxide, silicon nitride, an air gap, or a combination thereof. The supporter 31 may be an isolation layer between the vertical conductive lines 30 disposed adjacent to each other in the third direction D3. The supporter 31 may be referred to as a “vertical dielectric layer”. The supporter 31 may fill the first linear opening 18.

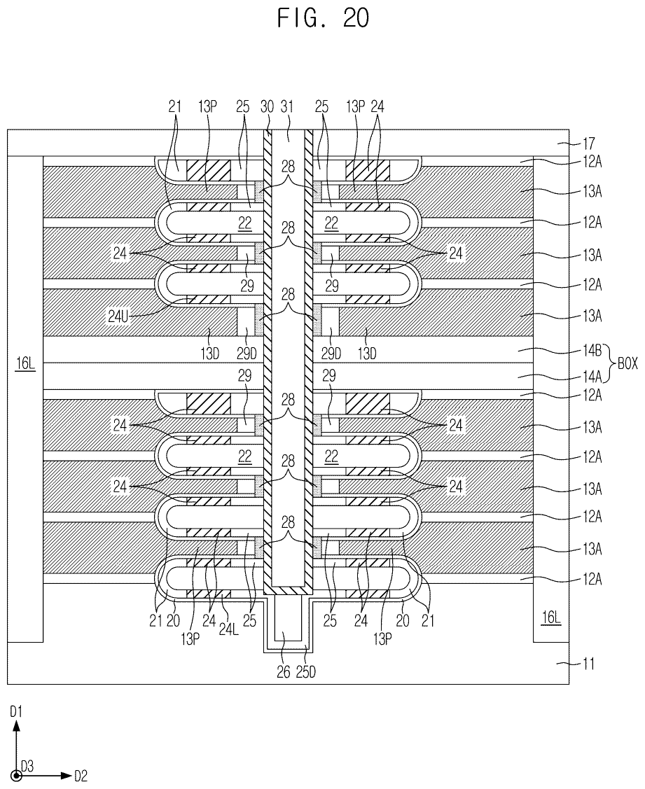

As illustrated in FIG. 21, a second hard mask layer 32 may be formed on a first hard mask layer 17, the vertical conductive line 30 and the supporter 31. The second hard mask layer 32 may include linear-shaped openings.

The second linear sacrificial layers 16L may be removed using the second hard mask layer 32 as a barrier. Accordingly, second linear openings 33 may be formed.

After the second linear openings 33 are formed, the first mold layers 12A may be selectively removed in the second direction D2 through the second linear openings 33. To selectively remove the first mold layers 12A, a difference in etch selectivity between the first mold layers 12A and the original body portions 13A may be used. The first mold layers 12A may be removed using a wet etch process or a dry etch process. For example, when the first mold layers 12A include a silicon germanium layer, and the original body portions 13A include a monocrystalline silicon layer, the silicon germanium layer may be etched using an etchant or etch gas having a selectivity with respect to the monocrystalline silicon layer. As the first mold layers 12A are removed, the upper and lower surfaces of the original body portions 13A may be exposed.

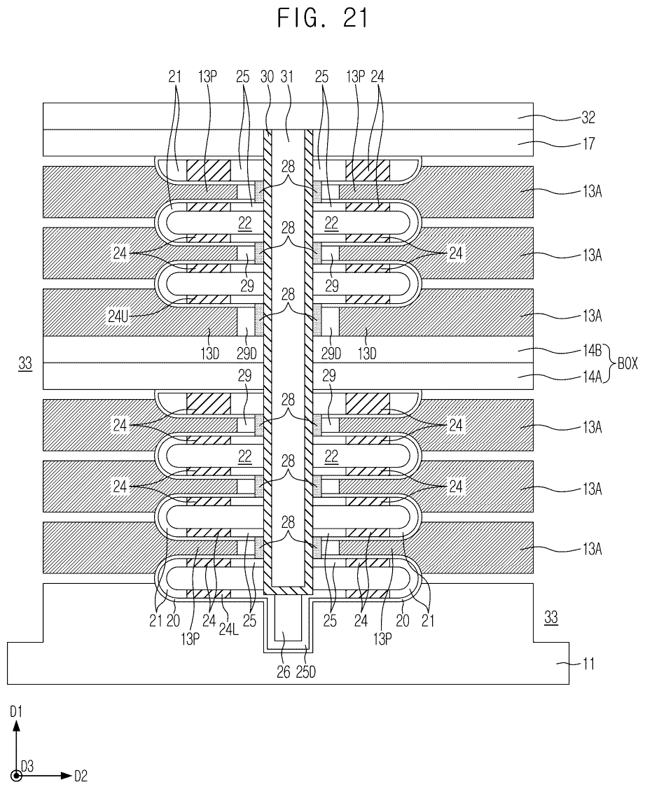

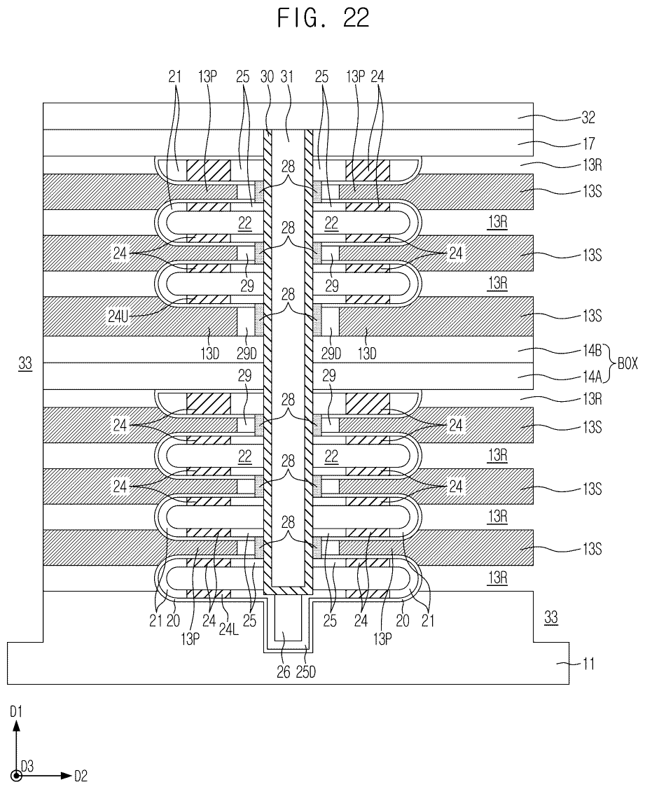

As illustrated in FIG. 22, the original body portions 13A may be selectively recessed using a wet or dry etch process. Vertical thicknesses of the original body portions 13A may decrease as indicated by reference numeral “13S”. Hereinafter, the original body portions 13A are referred to as “recessed body portions 13S”.

An inter-body recess 13R may be formed between the recessed body portions 13S vertically disposed.

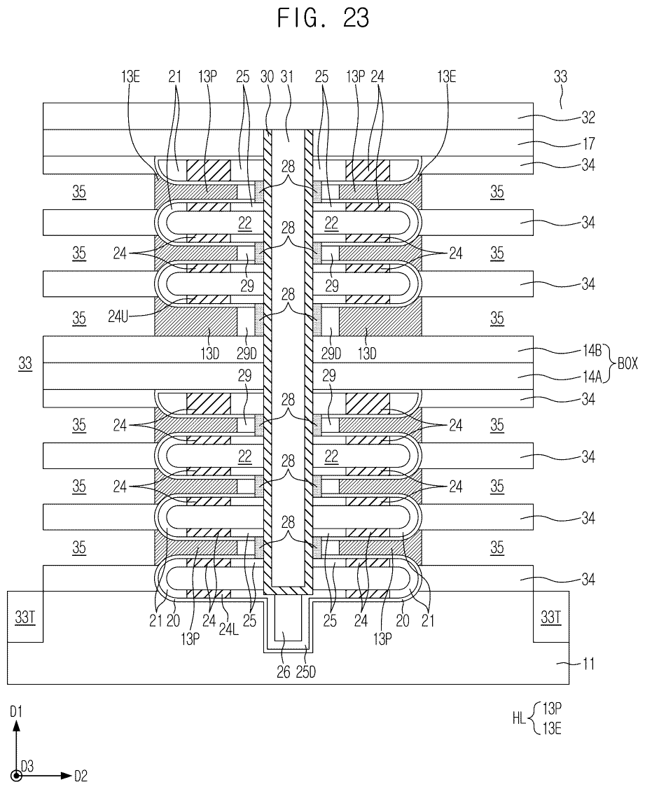

As illustrated in FIG. 23, second inter-cell horizontal dielectric layers 34 may be formed to fill the inter-body recesses 13R. The second inter-cell horizontal dielectric layers 34 may include silicon oxide.

After the second inter-cell horizontal dielectric layers 34 are formed, a second bottom protective layer 33T may be formed on the bottom of the second linear opening 33. The second bottom protective layer 33T may include a material having an etch selectivity with respect to the substrate 11. The second bottom protective layer 33T may include a dielectric material. The second bottom protective layer 33T may include silicon oxide, silicon nitride, silicon carbon oxide, or a combination thereof.

After the second bottom protective layer 33T is formed, storage openings 35 and wide sheets 13E may be formed by selective recessing of the recessed body portions 13S. The storage openings 35 may be referred to as “capacitor openings”. The wide sheets 13E may refer to the recessed body portions 13S remaining after the recessing. An average vertical height of the wide sheets 13E in the first direction DI may be greater than an average vertical height of the narrow sheets 13P. Thicknesses of the wide sheets 13E may gradually increase in the second direction D2. Horizontal lengths of the wide sheets 13E in the second direction D2 may be less than horizontal lengths of the narrow sheets 13P. The wide sheets 13E may each have a fan-like shape. The wide sheets 13E may be referred to as “fan-shaped sheets”, and the narrow sheets 13P may be referred to as “flat plate-shaped sheets”.

To form the wide sheets 13E, the recessed body portions 13S may be etched isotropically or anisotropically. One side of each of the wide sheets 13E, i.e., a side surface exposed by the storage opening 35, may have a flat shape. The one side of the wide sheet 13E may have various shapes. For example, the one side of the wide sheet 13E may have a rounded concave shape, a rounded convex shape, an angled concave shape, or an angled convex shape.

The second bottom protective layer 33T and a lowermost second inter-cell horizontal dielectric layer 34 may prevent loss of the substrate 11 during the recessing process of the recessed body portions 13S.

Each of the storage openings 35 may be disposed between the second inter-cell horizontal dielectric layers 34 in the first direction D1.

A portion of the bottom sheet 13D may be horizontally recessed while the wide sheets 13E are formed.

In some embodiments, the horizontal recessing of the recessed body portions 13S for forming the wide sheets 13E may stop at boundary regions of the narrow sheets 13P and the wide sheets 13E.

Each of the narrow sheets 13P and each of the wide sheets 13E may form a nano sheet HL.

The first spacer 21 may surround the wide sheets 13E at the same horizontal level disposed in the third direction D3, and the second spacer 25 may surround the narrow sheets 13P at the same horizontal level disposed in the third direction D3.

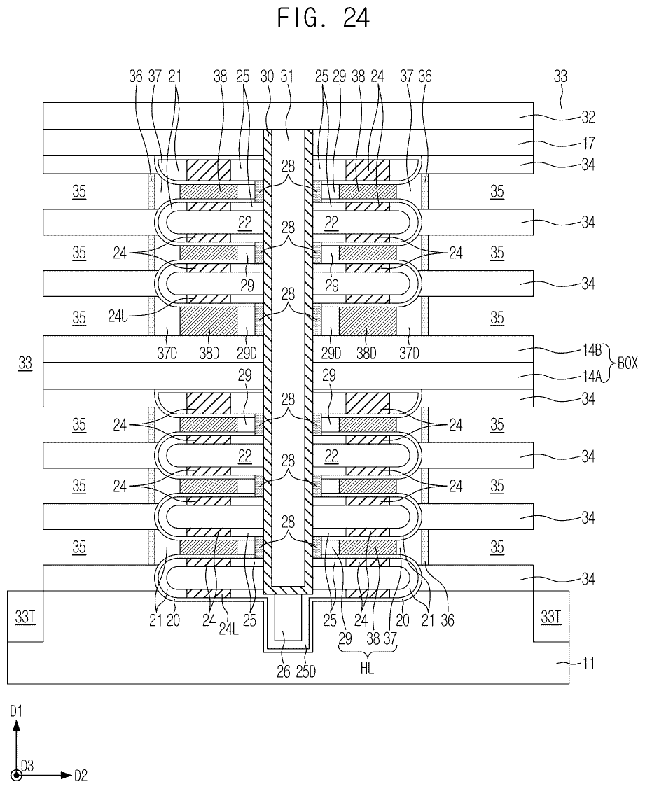

As illustrated in FIG. 24, a pre-cleaning process may be performed on the surfaces of the wide sheets 13E.

Second contact nodes 36 may be formed on the wide sheets 13E. Forming the second contact nodes 36 may include selective epitaxial growth (SEG). For example, a semiconductive material may be grown from side surfaces of the wide sheets 13E through the selective epitaxial growth (SEG). The second contact nodes 36 may include SEG Si. Because the wide sheets 13E include monocrystalline silicon, a silicon layer may be epitaxially grown along crystal surfaces of the side surfaces of the wide sheets 13E.

The second contact nodes 36 may include a dopant. When the silicon layer is grown using the selective epitaxial growth (SEG), dopants may be doped in situ. Therefore, the second contact nodes 36 may be doped epitaxial layers. The second contact nodes 36 may include an N-type dopant as a dopant. The N-type dopant may include phosphorus, arsenic, antimony, or a combination thereof. The second contact nodes 36 may include a phosphorus-doped silicon epitaxial layer, i.e., doped SEG SiP, formed by the selective epitaxial growth (SEG). In some embodiments, the second contact nodes 36 may be formed by deposition and etch-back processes of doped polysilicon.

Each of the second contact nodes 36 may be disposed between the second inter-cell horizontal dielectric layers 34 that are vertically stacked. The second contact nodes 36 may correspond to the second contact nodes SNC illustrated in FIG. 4B.

Second doped regions 37 may be formed in the wide sheets 13E. A heat treatment process may be performed to form the second doped regions 37, and therefore, dopants may be diffused from the second contact nodes 36. While the second doped regions 37 are formed, bottom second doped regions 37D may be formed in the bottom sheets 13D.

A channel 38 may be defined between each of the first doped regions 29 and each of the second doped regions 37. A horizontal arrangement of the first doped region 29, the channel 38 and the second doped region 37 may form the nano sheet HL. A bottom channel 38D may be defined between each of the bottom first doped regions 29D and each of the bottom second doped regions 37D. A horizontal arrangement of the bottom first doped region 29D, the bottom channel 38D and the bottom second doped region 37D may be formed in the bottom sheet 13D.

Each of the nano sheets HL may include the first doped region 29, the second doped region 37, and the channel 38. The first doped region 29 and the channel 38 may be formed in each of the narrow sheets 13P, and the second doped region 37 may be formed in each of the wide sheets 13E. A portion of the second doped region 37 may extend into the narrow sheet 13P. One side of the second doped region 37 of the nano sheet HL may be coupled to the channel 38, and the other side of the second doped region 37 of the nano sheet HL may be coupled to the second contact node 36.

The first spacer 21 may surround the second doped regions 37 at the same horizontal level disposed in the third direction D3, and the second spacer 25 may surround the first doped regions 29 at the same horizontal level disposed in the third direction D3. The horizontal conductive line 24 may surround the channels 38 at the same horizontal level disposed in the third direction D3.

In some embodiments, an ohmic contact layer including metal silicide may be further formed after the second contact nodes 36 are formed.

As described above, the second mold layers 13 of the mold stack SB may include the nano sheets HL formed by subsequent selective recessing processes, and each of the nano sheets HL may include the narrow sheet 13P and the wide sheet 13E. The first doped region 29 and the channel 38 may be formed in the narrow sheet 13P, and the second doped region 37 may be formed in the wide sheet 13E.

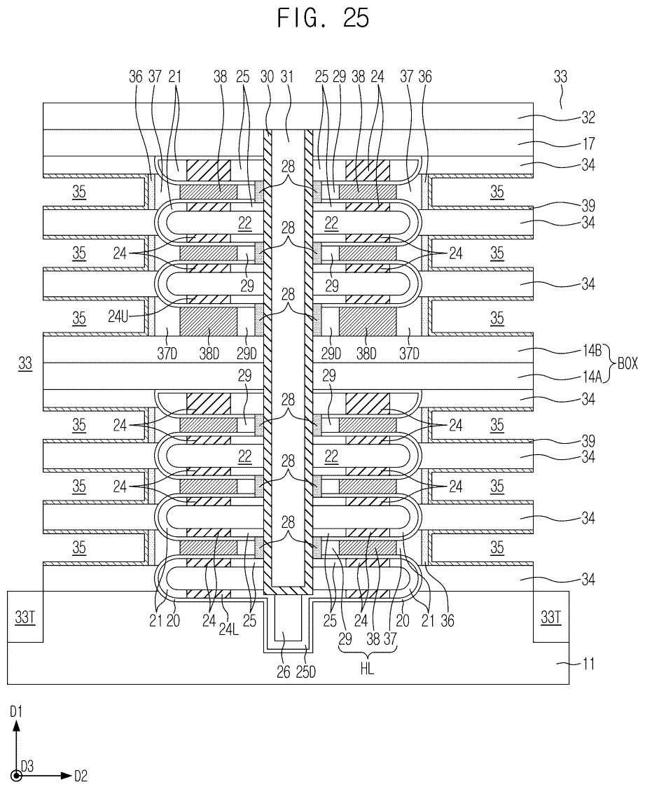

As illustrated in FIG. 25, first electrodes 39 of a data storage element may be formed on the second contact nodes 36. The first electrodes 39 may each have a horizontally-oriented cylindrical shape. Each of the first electrodes 39 may be disposed in a different one of the storage openings 35. The first electrodes 39 disposed adjacent to each other in the second direction D2 may be spaced apart from each other by the second linear openings 33. The first electrodes 39 disposed adjacent to each other in the first direction D1 may be spaced apart from each other by the second inter-cell horizontal dielectric layers 34. Forming the first electrodes 39 may include depositing a metal material, gap-filling a sacrificial material, and isolating the metal material in a vertical/horizontal direction. The sacrificial material may include oxide or polysilicon.

Each of the first electrodes 39 may include an inner space and a plurality of outer surfaces. The inner space of the first electrode 39 may include a plurality of inner surfaces. The outer surfaces of the first electrode 39 may include a vertical outer surface and a plurality of horizontal outer surfaces. The vertical outer surface of the first electrode 39 may vertically extend in the first direction D1, and the horizontal outer surfaces of the first electrode 39 may horizontally extend in the second direction D2 or the third direction D3. The inner space of the first electrode 39 may be a three-dimensional space. The first electrode 39 may have a cylindrical shape.

Among the outer surfaces of the first electrode 39, the vertical outer surface may be electrically coupled to the nano sheet HL and the second contact node 36.

The first electrode 39 may include metal, noble metal, metal nitride, conductive metal oxide, conductive noble metal oxide, metal carbide, metal silicide, or a combination thereof. For example, the first electrode 39 may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, or a combination thereof.

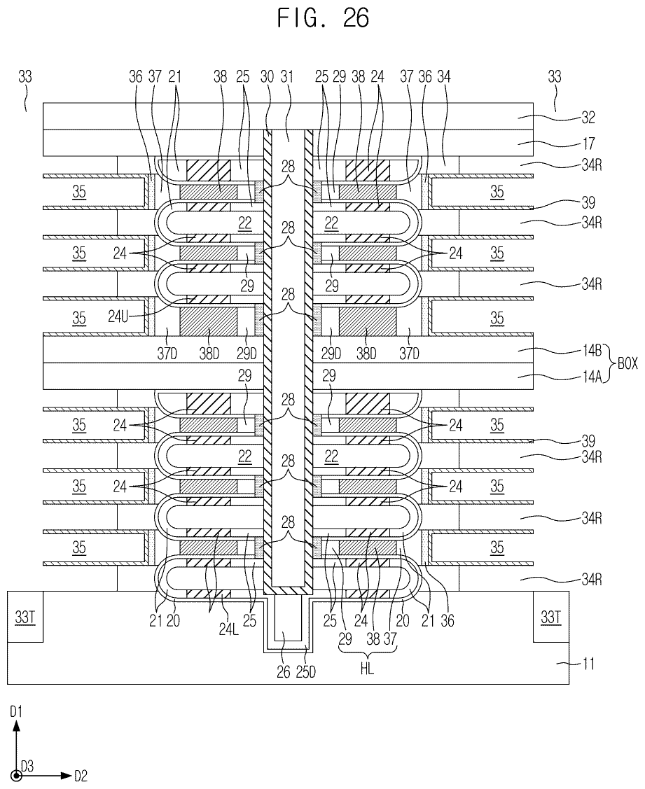

As illustrated in FIG. 26, portions of the second inter-cell horizontal dielectric layers 34 may be horizontally recessed (refer to reference numeral “34R”). Accordingly, outer walls of the first electrodes 39 may be partially exposed. The first electrodes 39 may each have a semi-cylindrical shape. A depth of horizontal recess of the second inter-cell horizontal dielectric layers 34 may be a depth that does not expose the second contact nodes 36. The semi-cylindrical shape of each of the first electrodes 39 may include cylindrical inner surfaces and semi-cylindrical outer surfaces.

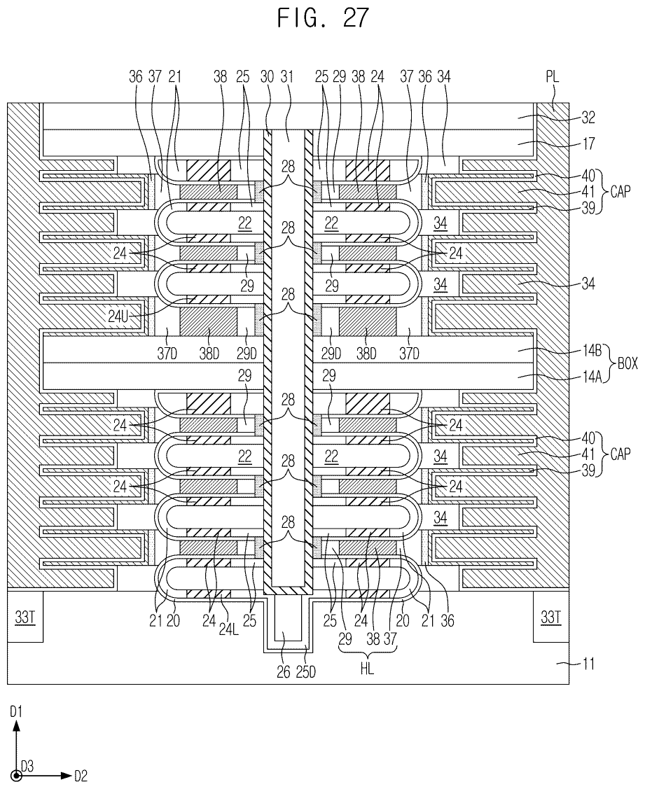

As illustrated in FIG. 27, a dielectric layer 40 and a second electrode 41 may be sequentially formed on the first electrodes 39. The first electrode 39, the dielectric layer 40 and the second electrode 41 may become a data storage element CAP. The second electrodes 41 of the data storage elements CAP may be merged with one another and become a common plate PL.

The dielectric layer 40 and the second electrode 41 may be disposed on the cylindrical inner surfaces of the first electrode 39. A portion of the dielectric layer 40 and a portion of the second electrode 41 may extend to be disposed on the semi-cylindrical outer surfaces of the first electrode 39. The second electrode 41 may vertically extend in the first direction D1.

The dielectric layer 40 may be referred to as a “capacitor dielectric layer” or a “memory layer”. The dielectric layer 40 may include silicon oxide, silicon nitride, a high-k material, a ferroelectric material, an antiferroelectric material, a perovskite material, or a combination thereof. The dielectric layer 40 may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). The dielectric layer 40 may include a ZA (ZrO₂/Al₂O₃) stack, a ZAZ (ZrO₂/Al₂O₃/ZrO₂) stack, a ZAZA (ZrO₂/A1₂O₃/ZrO₂/Al₂O₃) stack, a ZAZAZ (ZrO₂/Al₂O₃/ZrO₂/Al₂O₃/ZrO₂) stack, a HA (HfO₂/Al₂O₃) stack, a HAH (HfO₂/Al₂O₃/HfO₂) stack, a HAHA (HfO₂/Al₂O₃/HfO₂/Al₂O₃) stack, a HAHAH (HfO₂/Al₂O₃/HfO₂/Al₂O₃/HfO₂) stack, a HZAZH(HfO₂/ZrO₂/Al₂O₃/ZrO₂/HfO₂) stack, a ZHZAZHZ(ZrO₂/HfO₂/ZrO₂/Al₂O₃/ZrO₂/HfO₂/ZrO₂) stack, a HZHZ(HfO₂/ZrO₂/HfO₂/ZrO₂) stack, or AHZAZHA(Al₂O₃/HfO₂/ZrO₂/Al₂O₃/ZrO₂/HfO₂/Al₂O₃) stack.

The second electrode 41 may include metal, noble metal, metal nitride, conductive metal oxide, conductive noble metal oxide, metal carbide, metal silicide, or a combination thereof. For example, the second electrode 41 may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, a titanium silicon nitride/titanium nitride/tungsten (TiSiN/TiN/W) stack, or a combination thereof. The second electrode 41 may also include a combination of a metal-based material and a silicon-based material. For example, titanium nitride, tungsten and polysilicon may be sequentially stacked in the second electrode 41.

In some embodiments, an interface control layer may be further formed between the first electrode 39 and the dielectric layer 40 to alleviate leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode 41 and the dielectric layer 40.

In some embodiments, the recessing of the second inter-cell horizontal dielectric layers 34 illustrated in FIG. 26 may be omitted. Thereafter, as illustrated in FIG. 27, the dielectric layer 40 and the second electrode 41 may be formed. Accordingly, the data storage element CAP including the first electrode 39 having a concave shape may be formed.

According to FIGS. 5 to 27, a method for fabricating the semiconductor device in accordance with an embodiment may include forming the first mold stack SB10 in which the first mold layers 12 are alternately stacked with the second mold layers 13 on the substrate 11, forming the first bonding layer 14A on the first mold stack SB10, forming the second mold stack SB11 in which the first mold layers 12 are alternately stacked with the second mold layers 13 on the sacrificial substrate 11A, forming the second bonding layer 14B on the second mold stack SB11, flipping the sacrificial substrate 11A on which the second mold stack SB11 is formed, to bond the first bonding layer 14A and the second bonding layer 14B, removing the sacrificial substrate 11A, forming the narrow sheets 13P and the original body portions 13A by selectively recessing the second mold layers 13 of the first and second mold stacks SB10 and SB11, forming the horizontal conductive lines 24 surrounding the narrow sheets 13P, forming the vertical conductive line 30 coupled in common to one side surfaces of the narrow sheets 13P, forming the wide sheets 13E by selectively recessing the original body portions 13A, and forming the data storage elements CAP each coupled to a different one of the wide sheets 13E.

According to an embodiment described above, because the first and second mold stacks SB10 and SB11 including the epitaxially-grown first and second mold layers 12 and 13 are bonded through wafer bonding when a three-dimensional array of memory cells is formed, it is possible to form a dislocation-free epitaxial growth structure with a high stack density, and therefore, a number of layers of the memory cells may increase.

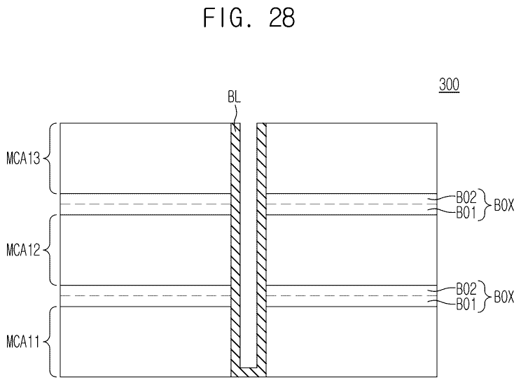

FIG. 28 is a schematic cross-sectional view of a semiconductor device 300 in accordance with an embodiment of the present disclosure.

As illustrated in FIG. 28, the semiconductor device 300 may include three memory cell array stacks MCA11, MCA12 and MCA13 and three bonding structures BOX. Each of the bonding structures BOX may be disposed between the memory cell array stacks MCA11, MCA12 and MCA13. The memory cell array stacks MCA11, MCA12 and MCA13 may share a vertical conductive line BL. The vertical conductive line BL may penetrate the bonding structures BOX. The memory cell array stacks MCA11, MCA12 and MCA13 may include a first memory cell array stack MCA11, a second memory cell array stack MCA12, and a third memory cell array stack MCA3. Each of the first to third memory cell array stacks MCA11, MCA12 and MCA13 may include a three-dimensional array of memory cells.

Each of the bonding structures BOX may have a double structure of a first bonding dielectric layer BO1 and a second bonding dielectric layer BO2. The first and second bonding dielectric layers BO1 and BO2 may include SiO₂, SiN, SiCN, SiCO, SiCON, or a combination thereof.

In some embodiments, the semiconductor device 300 may have at least four or more memory cell array stacks vertically stacked through the bonding structures BOX.

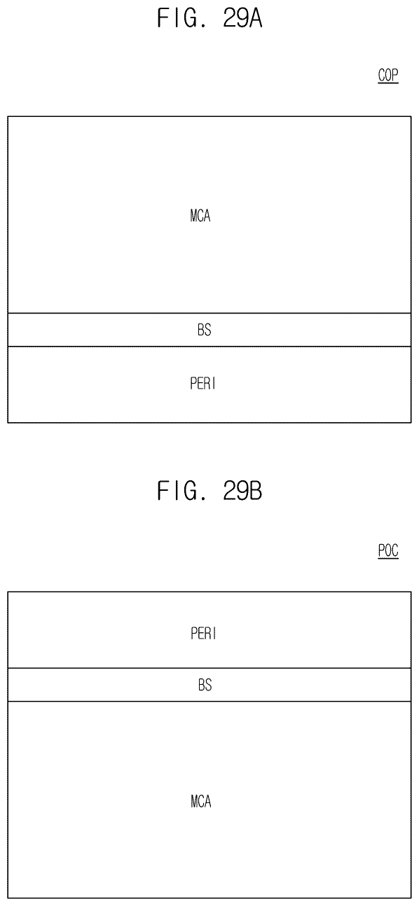

FIGS. 29A and 29B are schematic cross-sectional views of a semiconductor device in accordance with embodiments of the present disclosure.

As illustrated in FIG. 29A, a semiconductor device COP may include a memory cell array MCA, a peripheral circuit portion PERI, and a bonding interface BS. The bonding interface BS may be disposed between the memory cell array MCA and the peripheral circuit portion PERI. In the semiconductor device COP, the memory cell array MCA may be disposed at a higher level than the peripheral circuit portion PERI. The semiconductor device COP may be referred to as a “Peri Under Cell array (PUC) structure”. The memory cell array MCA may include a substrate on which back grinding is performed and an array of memory cells. For example, as described with reference to FIG. 27, after the data storage element CAP is formed, the substrate 11 may be flipped over through a wafer flip, and then the substrate 11 may be partially ground back.

As illustrated in FIG. 29B, a semiconductor device POC may include a memory cell array MCA, a peripheral circuit portion PERI, and a bonding interface BS. The bonding interface BS may be disposed between the memory cell array MCA and the peripheral circuit portion PERI. In the semiconductor device POC, the memory cell array MCA may be disposed at a lower level than the peripheral circuit portion PERI. The semiconductor device POC may be referred to as a “Cell array Under Peri (CUP) structure”. Forming the peripheral circuit portion PERI may include forming a plurality of control circuits on a peripheral circuit substrate and forming multi-level interconnection on the control circuits.

In FIG. 29A and FIG. 29B, the memory cell array MCA may include the semiconductor device 300 illustrated in FIG. 28. That is, the memory cell array MCA illustrated in FIGS. 29A and 29B may include at least one or more of the memory cell array stacks MCA11, MCA12 and MCA13 and at least one or more of the bonding structures BOX. In some embodiments, the memory cell array MCA illustrated in FIGS. 29A and 29B may include a stack of the lower-level array stack MCA10, the bonding structure BOX and the upper-level array stack MCA20, as described with reference to FIG. 4A.

In FIG. 29A and FIG. 29B, the bonding interface BS may include pad bonding, hybrid bonding, oxide-to-oxide bonding, metal-to-metal bonding, or a combination thereof. The hybrid bonding may refer to a combination of the pad bonding and the oxide-to-oxide bonding. The pad bonding may include forming a cell bonding pad for a memory cell array, forming a peripheral circuit bonding pad for a peripheral circuit portion, performing a wafer flip so that the cell bonding pad and the peripheral circuit bonding pad face each other, and performing wafer bonding.

The semiconductor device COP illustrated in FIG. 29A may perform the wafer flip on the substrate on which the memory cell array is formed so that the cell bonding pad and the peripheral circuit bonding pad face each other, after the cell bonding pad and the peripheral circuit bonding pad are formed. The semiconductor device POC illustrated in FIG. 29B may perform the wafer flip on the substrate on which the peripheral circuit portion is formed so that the cell bonding pad and the peripheral circuit bonding pad face each other, after the cell bonding pad and the peripheral circuit bonding pad are formed.

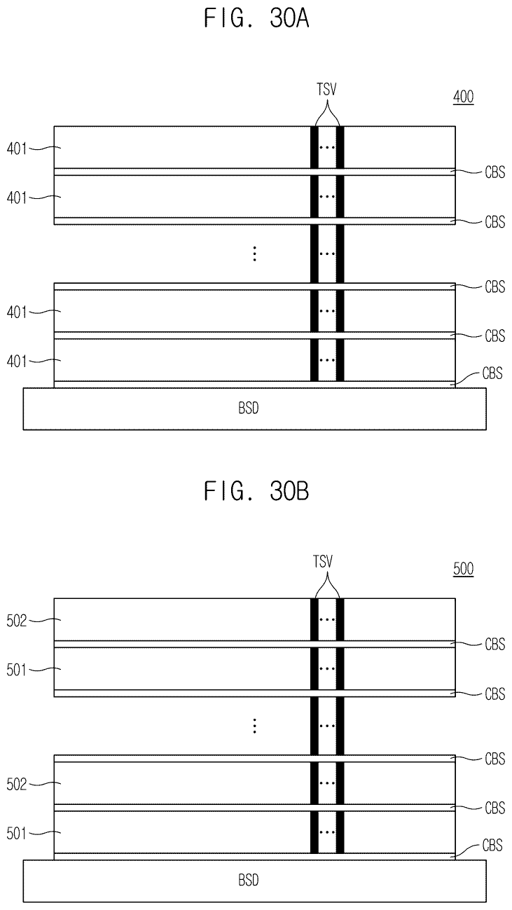

FIGS. 30A and 30B illustrate various views illustrating a stack assembly in accordance with embodiments of the present disclosure.

As illustrated in FIG. 30A, a stack assembly 400 may include an assembly of semiconductor dies. For example, the stack assembly 400 may include a first semiconductor die BSD and a plurality of second semiconductor dies 401. The first semiconductor die BSD may include logic circuits. Each of the second semiconductor dies 401 may include memory cell array stacks according to embodiments described above. Each of the second semiconductor dies 401 may include at least one or more of the memory cell array stacks MCA11, MCA12 and MCA13 and at least one or more of the bonding structures BOX described with reference to FIG. 28.

Each of the second semiconductor dies 401 may include structures in which a memory cell array stack and a peripheral circuit portion are stacked, for example, the semiconductor device COP illustrated in FIG. 29A or the semiconductor device POC illustrated in FIG. 29B. The logic circuits of the first semiconductor die BSD may be different from the peripheral circuit portions of the second semiconductor dies 401. The second semiconductor dies 401 may have chip levels or wafer levels.

The second semiconductor dies 401 may be electrically coupled to each other through a plurality of through silicon vias TSV and bonding interfaces CBS. The first semiconductor die BSD and a lowermost second semiconductor die 401 may be electrically coupled to each other through the bonding interface CBS. The second semiconductor dies 401 may be referred to as “core dies”, “semiconductor chips”, or “memory chips”.

The bonding interface CBS may include micro-bump, pad bonding, hybrid bonding, oxide-to-oxide bonding, metal-to-metal bonding, or a combination thereof.

As illustrated in FIG. 30B, a stack assembly 500 may include an assembly of semiconductor dies. For example, the stack assembly 500 may include a first semiconductor die BSD, a plurality of second semiconductor dies 501, and a plurality of third semiconductor dies 502. The first semiconductor die BSD may include logic circuits. Each of the second semiconductor dies 501 and each of the third semiconductor dies 502 may include memory cell array stacks according to embodiments described above. The second semiconductor dies 501 and the third semiconductor dies 502 may have different structures. For example, each of the second semiconductor dies 501 and each of the third semiconductor dies 502 may include at least one or more of the memory cell array stacks MCA11, MCA12 and MCA13 and at least one or more of the bonding structures BOX described with reference to FIG. 28.

Each of the second semiconductor dies 501 may include the semiconductor device COP illustrated in FIG. 29A in which a memory cell array is stacked over a peripheral circuit portion. Each of the third semiconductor dies 502 may include the semiconductor device POC illustrated in FIG. 29B in which a peripheral circuit portion is stacked over a memory cell array.

In some embodiments, each of the second semiconductor dies 501 may include the semiconductor device POC illustrated in FIG. 29B in which a peripheral circuit portion is stacked over a memory cell array, and each of the third semiconductor dies 502 may include the semiconductor device COP illustrated in FIG. 29A in which a memory cell array is stacked over a peripheral circuit portion.

The logic circuits of the first semiconductor die BSD may be different from the peripheral circuit portions of the second and third semiconductor dies 501 and 502. The second and third semiconductor dies 501 and 502 may have chip levels or wafer levels.

The second and third semiconductor dies 501 and 502 may be electrically coupled to each other through a plurality of through silicon vias TSV and bonding interfaces CBS. The first semiconductor die BSD and a lowermost second semiconductor die 501 may be electrically coupled to each other through the bonding interface CBS. The second and third semiconductor dies 501 and 502 may be referred to as “core dies”, “semiconductor chips”, or “memory chips”.

The bonding interface CBS may include micro-bump, pad bonding, hybrid bonding, oxide-to-oxide bonding, metal-to-metal bonding, or a combination thereof.

The stack assemblies 400 and 500 illustrated in FIGS. 30A and 30B may be high bandwidth memories.

According to various embodiments of the present disclosure, because mold stacks are bonded through wafer bonding when a three-dimensional array of memory cells is formed, it is possible to form a dislocation-free epitaxial growth structure, and therefore, a number of layers of the memory cells may increase.

According to various embodiments of the present disclosure, it is possible to form a dislocation-free silicon layer/silicon germanium layer stack with a high stack through wafer bonding.

While the embodiments of the present disclosure have been illustrated and described with respect to specific embodiments and drawings, the disclosed embodiments are not intended to be restrictive. Further, it is noted that the embodiments may be achieved in various ways through substitution, change, and modification, as those skilled in the art will recognize in light of the present disclosure, without departing from the spirit and/or scope of the present disclosure and the following claims. Furthermore, the embodiments may be combined to form additional embodiments.

What is claimed is:

1. A method for fabricating a semiconductor device, the method comprising:
forming a first mold stack and a first bonding layer on a substrate;
forming a second mold stack and a second bonding layer on a sacrificial substrate;
flipping the sacrificial substrate and bonding the first and second bonding layers;
removing the sacrificial substrate; and
forming a plurality of memory cells vertically stacked in the first and second mold stacks.

2. The method of claim 1, wherein forming the memory cells vertically stacked includes:
replacing the first mold stack with the memory cells and forming a lower-level array stack of the memory cells; and
replacing the second mold stack with the memory cells and forming an upper-level array stack of the memory cells.

3. The method of claim 1, wherein the first and second bonding layers each include a dielectric material.

4. The method of claim 1, wherein the first and second bonding layers each include SiO₂, SiN, SiCN, SiCO, SiCON, or a combination thereof.

5. The method of claim 1, wherein the substrate and the sacrificial substrate each include monocrystalline silicon.

6. The method of claim 1, wherein in each of the first and second mold stacks, first semiconductor layers are alternately stacked with second semiconductor layers so that the first semiconductor layers and the second semiconductor layers are epitaxially grown.

7. The method of claim 5, wherein in each of the first and second mold stacks, the first semiconductor layers include silicon germanium, and the second semiconductor layers include monocrystalline silicon.

8. The method of claim 1, wherein the first and second mold stacks each include a stack of dislocation-free epitaxially grown layers.

9. The method of claim 1, wherein forming the plurality of memory cells vertically stacked includes:
forming nano sheets;
forming horizontal conductive lines surrounding the nano sheets;
forming a vertical conductive line coupled to one side of each of the nano sheets; and
forming data storage elements coupled to the other side of each of the nano sheets.

10. A semiconductor device comprising:
a lower-level array stack of first memory cells;
an upper-level array stack of second memory cells;
a bonding structure between the lower-level array stack and the upper-level array stack; and
a vertical conductive line penetrating the bonding structure and coupled in common to the first memory cells and the second memory cells.

11. The semiconductor device of claim 10, wherein the bonding structure includes a dielectric material.

12. The semiconductor device of claim 10, wherein the bonding structure includes SiO₂, SiN, SiCN, SiCO, SiCON, or a combination thereof.

13. The semiconductor device of claim 10, wherein the bonding structure includes a double bonding layer.

14. The semiconductor device of claim 10, wherein the bonding structure includes oxide-to-oxide bonding.

15. The semiconductor device of claim 10, wherein the first memory cells and the second memory cells are vertically stacked, and
wherein each of the first and second memory cells includes:
a horizontally-oriented nano sheet;
a vertical conductive line coupled to one side of the nano sheet;
a horizontal conductive line surrounding the nano sheet; and
a data storage element coupled to the other side of the nano sheet.

16. The semiconductor device of claim 15, wherein the data storage element includes:
a first electrode coupled to the nano sheet;
a dielectric layer on the first electrode; and
a second electrode on the dielectric layer.

17. A method for fabricating a semiconductor device, the method comprising:
forming a first structure comprising a first mold stack and a first bonding layer on a substrate;
forming a second structure comprising a second mold stack and a second bonding layer on a sacrificial substrate;
flipping the second structure and positioning the flipped second structure on the first structure with the first and second bonding layers being adjacent to each other;
bonding the first and second bonding layers;
after bonding the first and second bonding layers removing the sacrificial substrate; and
forming a plurality of memory cells vertically stacked in the first and second mold stacks.
